(19) United States
(12) Patent Application Publication
(10) Pub. No.: US 2022/0291590 A1
(43) Pub. Date: Sep. 15, 2022

(54) MODELING METHOD FOR COMPUTATIONAL FINGERPRINTS

(71) Applicant: ASML NETHERLANDS B.V., Veldhoven (NL)

(72) Inventors: Jing SU, Fremont, CA (US); Yana CHENG, San Jose, CA (US); Zchenxi LIN, Newark, CA (US); Yi ZOU, Foster City, CA (US); Ddavit HARUTYUNYAN, San Jose, CA (US); Emil Peter SCHMITT-WEAVER, Boise, ID (US); Kaustuve BHATTACHARYYA, Veldhoven (NL); Cornelis Johannes Henricus LAMBREGTS, Geldrop (NL); Hadi YAGUBIZADE, Eindhoven (NL)

(73) Assignee: ASML NETHERLANDS B.V., Veldhoven (NL)

(21) Appl. No.: 17/634,309

(22) PCT Filed: Jul. 9, 2020
(86) PCT No.: PCT/EP2020/069355

§ 371 Date: Feb. 10, 2022

Related U.S. Application Data
(60) Provisional application No. 62/886,208, filed on Aug. 13, 2019.
(60) Provisional application No. 62/943,505, filed on Dec. 4, 2019.
(60) Provisional application No. 63/044,027, filed on Jun. 25, 2020.

(51) Int. Cl. G03F 7/20

(52) U.S. Cl. CPC G03F 7/705; G03F 7/70633; G03F 7/70508; H01L 22/20

(57) ABSTRACT

A method for determining a model to predict overlay data associated with a current substrate being patterned. The method involves obtaining (i) a first data set associated with one or more prior layers and/or current layer of the current substrate, (ii) a second data set including overlay metrology data associated with one or more prior substrates, and (iii) de-corrected measured overlay data associated with the current layer of the current substrate; and determining, based on (i) the first data set, (ii) the second data set, and (iii) the de-corrected measured overlay data, values of a set of model parameters associated with the model such that the model predicts overlay data for the current substrate, wherein the values are determined such that a cost function is minimized, the cost function comprising a difference between the predicted data and the de-corrected measured overlay data.

### CROSS-REFERENCE TO RELATED APPLICATIONS

This application claims priority of U.S. application 62/886,208 which was filed on Aug. 13, 2019, U.S. application 62/943,505 which was filed on Dec. 4, 2019, and U.S. application 63/044,027 which was filed on Jun. 25, 2020 which are incorporated herein in its entirety by reference.

### TECHNICAL FIELD

The description herein relates generally to apparatus and methods of a patterning process and determining fingerprints corresponding to a design layout.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

### SUMMARY

According to an embodiment, the present disclosure describes a method for determining a model to predict overlay data associated with a current substrate being patterned, the method comprising: obtaining (i) a first data set associated with one or more prior layers and/or current layer of the current substrate being patterned, (ii) a second data set comprising overlay metrology data associated with one or more prior substrates that were patterned before the current substrate, and (iii) de-corrected measured overlay data associated with the current layer of the current substrate; and determining, based on (i) the first data set, (ii) the second data set, and (iii) the de-corrected measured overlay data, values of a set of model parameters associated with the model such that the model predicts the overlay data for the current substrate, wherein the values of the model parameters are determined such that a cost function is minimized, the cost function comprises a difference between the predicted overlay data and the de-corrected measured overlay data.

Furthermore, in an embodiment, there is provided a computer program product comprising a non-transitory computer readable medium having instructions recorded thereon, the instructions when executed by a computer implementing the steps of the method of any of the embodiments above.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 shows a block diagram of various subsystems of a lithography system, according to an embodiment;

FIG. 2 illustrates a lithographic cell or cluster, according to an embodiment;

FIG. 3 illustrates schematically measurement and exposure processes associated with the lithographic apparatus, according to an embodiment;

FIG. 4A illustrates an example model configured to predict a de-corrected overlay data (or fingerprint), according to an embodiment;

FIG. 4B illustrates an example cost function used for training the model of FIG. 4A, the cost function shown as a difference between the predicted overlay data map and a measured de-corrected overlay map, according to an embodiment;

FIG. 5 illustrates example point-level data used to train the point-level model, according to an embodiment;

FIG. 6 illustrates example decomposition of the overlay map based on basis function related to both inter-filed and intra-filed components, according to an embodiment;

FIG. 7 is a flow chart of a method for determining a model to predict de-corrected overlay data associated with a current substrate being patterned, according to an embodiment;

FIG. 8 is a flow chart of a method for updating the trained model (e.g., of FIG. 7) to predict a de-corrected overlay data associated with a current substrate being patterned, according to an embodiment;

FIG. 9 illustrates example overlay correction based on prior lot substrates and predicted overlay of current substrate, according to an embodiment;

FIG. 10 is a flow chart of a method of determining overlay corrections for a current substrate to be patterned, according to an embodiment;

FIG. 11 is an example of building an overlay prediction model using alignment data and overlay data, according to an embodiment;

FIG. 12 illustrates example per field data (e.g., overlay data) for training a model, according to an embodiment;

FIG. 13 illustrates an example overlay data, according to an embodiment;

FIG. 14 is a block diagram of an exemplary feed forward correction of a patterning process, according to an embodiment;

FIG. 15 is a flow chart of a method for training a model, according to an embodiment;

FIG. 16 is a flow chart of a method for controlling a patterning process based on predictions from the trained model of FIG. 15, according to an embodiment;

FIG. 17 schematically depicts an embodiment of a scanning electron microscope (SEM), according to an embodiment;

FIG. 18 schematically depicts an embodiment of an electron beam inspection apparatus, according to an embodiment;

FIG. 19 schematically depicts an example inspection apparatus and metrology technique, according to an embodiment;

FIG. 20 schematically depicts an example inspection apparatus, according to an embodiment;

FIG. 21 illustrates the relationship between an illumination spot of an inspection apparatus and a metrology target, according to an embodiment;

FIG. 22 schematically depicts a process of deriving a plurality of variables of interest based on measurement data, according to an embodiment;

FIG. 23 is a block diagram of an example computer system, according to an embodiment;

FIG. 24 is a schematic diagram of a lithographic projection apparatus, according to an embodiment;

FIG. 25 is a schematic diagram of another lithographic projection apparatus, according to an embodiment;

FIG. 26 is a more detailed view of the apparatus in FIG. 25, according to an embodiment;

FIG. 27 is a more detailed view of the source collector module SO of the apparatus of

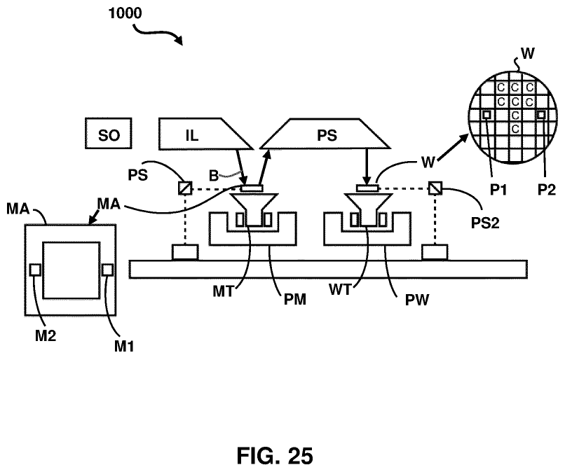

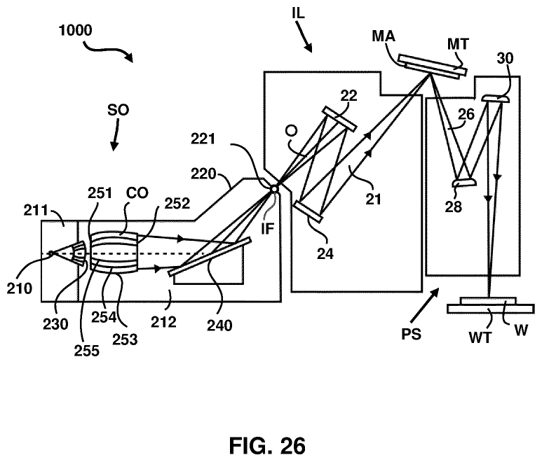

FIG. 25 and FIG. 26, according to an embodiment.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The pattern layout design may include, as an example, application of resolution enhancement techniques, such as optical proximity corrections (OPC). OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, the term “mask,” “patterning device” and “design layout” can be used interchangeably, as in the context of RET, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another or non-geometrical optical effects such as diffraction and interference. Similarly, proximity effects may arise from diffusion and other chemical effects during post-exposure bake (PEB), resist development, and etching that generally follow lithography.

Before describing embodiments in detail, it is instructive to present an example environment in which embodiments may be implemented.

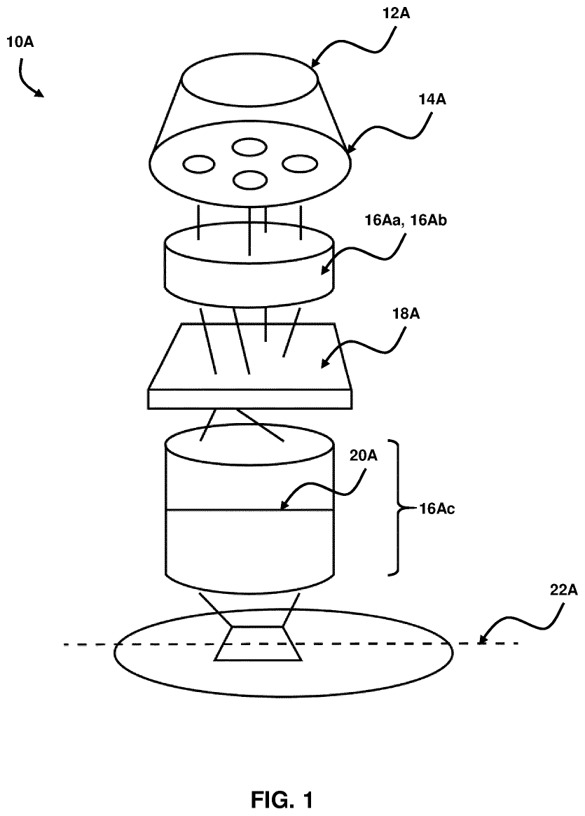

FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it may be desirable to separate the optical properties of the patterning device from the optical properties of the rest of the lithographic projection apparatus including at least the source and the projection optics.

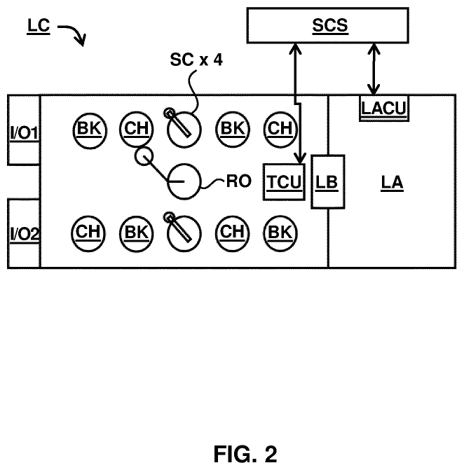

FIG. 2 illustrates a lithographic cell or cluster. the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers DE to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently, it is desirable to inspect an exposed substrate to measure or determine one or more properties such as overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system MET which receives some or all of the substrates W that have been processed in the lithocell. The metrology system MET may be part of the lithocell LC, for example it may be part of the lithographic apparatus LA.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which are good.

Within a metrology system MET, a metrology apparatus is used to determine one or more properties of the substrate, and in particular, how one or more properties of different substrates vary or different layers of the same substrate vary from layer to layer. The metrology apparatus may be integrated into the lithographic apparatus LA or the lithocell LC or may be a stand-alone device. To enable rapid measurement, it is desirable that the metrology apparatus measure one or more properties in the exposed resist layer immediately after the exposure. However, the latent image in the resist has a low contrast—there is only a very small difference in refractive index between the parts of the resist which have been exposed to radiation and those which have not—and not all metrology apparatus have sufficient sensitivity to make useful measurements of the latent image. Therefore measurements may be taken after the post-exposure bake step (PEB) which is customarily the first step carried out on an exposed substrate and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of a faulty substrate but may still provide useful information.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

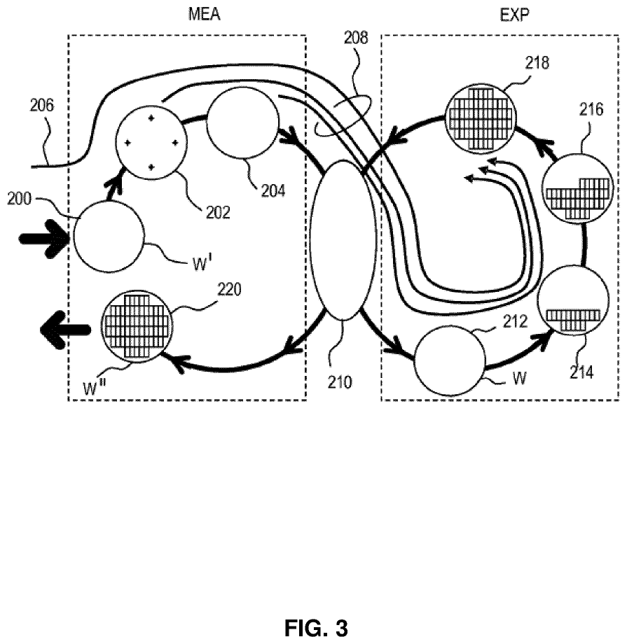

FIG. 3 illustrates schematically measurement and exposure processes, e.g., involving the apparatus of FIG. 1 which includes the steps to expose target portions (e.g. dies) on a substrate W in the dual stage apparatus of FIG. 1. On the left-handed side within a dotted box steps are performed at a measurement station MEA, while the right-handed side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the purpose of improving overlay performance, the task is to ensure that new patterns are applied in the correct position on a substrate that has already been subjected to one or more cycles of patterning and processing. These processing steps progressively introduce distortions in the substrate that can be measured and corrected for to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore, some layers may be exposed in an immersion-type lithography tool, while others are exposed in a “dry”′ tool. Some layers may be exposed in a tool working at DUV wavelengths, while others are exposed using EUV wavelength radiation.

At 202, alignment measurements using the substrate marks Pl, etc., and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid,” which maps very accurately the distribution of marks across the substrate, including any distortion relative to a nominal rectangular grid.

At step 204, a map of wafer height (Z) against the X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. These recipe data are added to the measurements of wafer position, wafer grid, and height map that were made at 202, 204, and then a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the “ideal” grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station, and the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example, rather than measuring alignment in a single pass, often there will be separate phases of coarse and fine measurement, using the same or different marks. The coarse and/or fine alignment measurement steps can be performed before or after the height measurement, or interleaved.

In one embodiment, optical position sensors, such as alignment sensor AS, use visible and/or near-infra-red (NIR) radiation to read alignment marks. In some processes, processing of layers on the substrate after the alignment mark has been formed leads to situations in which the marks cannot be found by such an alignment sensor due to low or no signal strength.

A key performance parameter of the lithographic process is the overlay error. This error, often referred to simply as “overlay” is the error in placing a product features in the correct position relative to features formed in previous layers. As product feature become all that much smaller, overlay specifications become ever tighter.

Currently, e.g., in a run-to-run method, the overlay error is controlled using an exponential weighted average of de-corrected overlay fingerprints of limited number of sampled substrates from a previous lots to control the incoming lot (e.g., 5 out of 25 substrates are sampled). Existing methods are lot-based methods which means all substrates in the incoming lot will receive the same correction. Such correction is also referred as feedback (FB) control. The existing method (e.g., run-to-run FB method) has two assumptions: 1) a substrate-to-substrate overlay variation within the lot is small, and 2) a temporal lot-to-lot overlay variation is slow. In other words, overlay errors change slowly enough over a period of time between different lots that averaging the overlay errors of a particular lot may be used without affecting a performance (e.g., overlay specification, yield, etc.) of the patterning process. However, these two assumptions are becoming problematic as technology node shrinks to a single digit nanometer scale. Additional overlay determination methods and overlay based control are discussed in US patent publication numbers US2013230797A1, US2012008127A1, and US20180292761A1 incorporated herein in its entirety by reference.

In the present disclosure, methods described herein use metrology data and context information (e.g., information related to processing tools used in the patterning process) of all process layers up to a current layer being patterned, as well as the overlay data of previous lots to predict the overlay data for every substrate in the incoming lot. In an embodiment, context information refers to for example, information related to processing tools used in the patterning process such as in FIG. 2 and FIG. 3.

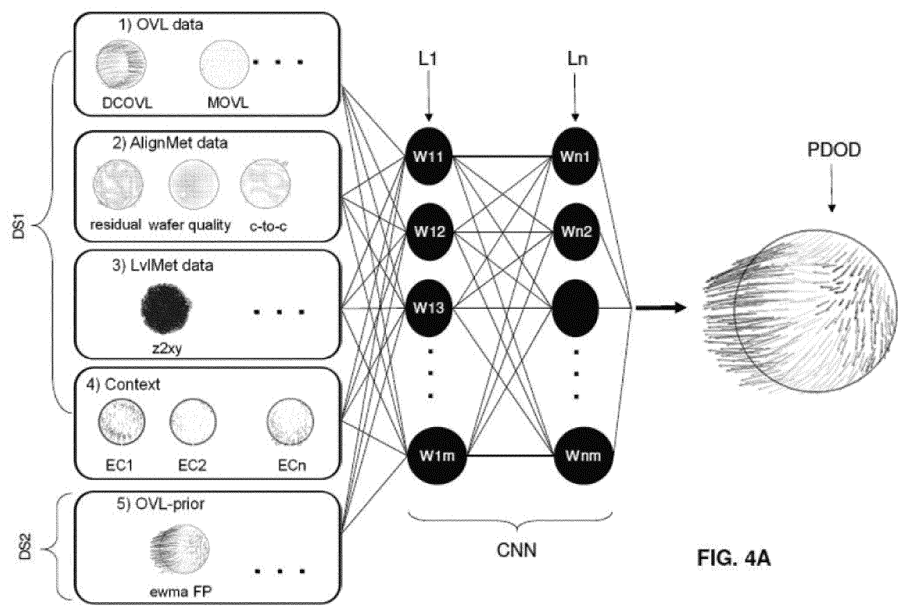

In an embodiment, the term “data” may refer to a map or a fingerprint when the data is represented as a 2D plot across a substrate, where the values of the data create a particular pattern (e.g., a fingerprint) associated with the data. For example, overlay data associated with a layer (or a substrate) may also be referred as an overlay fingerprint, where the magnitude and direction of the values of overlay when plotted at a substrate-level creates a particular pattern (or distribution). In an embodiment, the term “data” may also refer to a pixelated image, where intensity values of each pixel are related to values of the data (e.g., overlay, metrology, alignment, leveling, etc.) being represented. Specifically, depending on the type of model being trained, the data may be configured or converted to appropriate form to be processed by the model. In the example illustrated in FIGS. 4A and 4B a convolutional neural network (CNN) model is employed, but the present disclosure does not limit the model to a particular model type. Furthermore, based on data used to determine the model, the model may be referred as a point-level model or a substrate-level model. Each model and respective training process is discussed in detail throughout the specification.

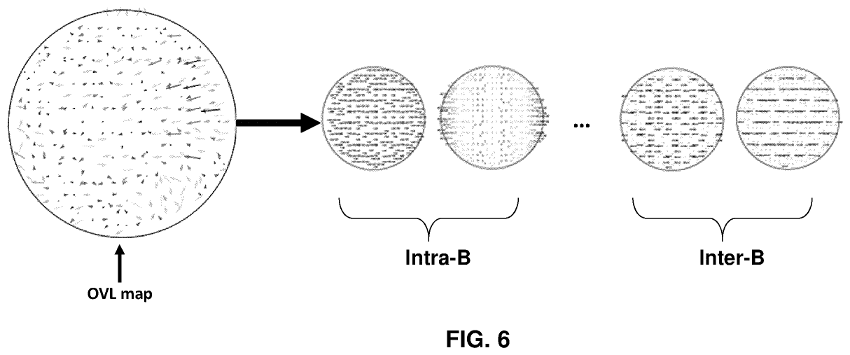

FIG. 4A illustrates an example model configured to predict a de-corrected overlay data (or fingerprint) for a current layer of a substrate being patterned. In an present example, the model is a machine learning model (e.g., CNN) comprising several layers L1, L2, . . . , Ln. Each layer is associated with model parameters (e.g., weights of each layer). For example, a first layer L1 is characterized by weights w1, w2, w13, . . . , w1n. In an embodiment, the training process involves iteratively modifying weights of one or more layers such that the predicted de-corrected overlay data (or its image) is as close as possible to a ground truth image (e.g., an image of measured de-corrected overlay data). The training of the example CNN model is based on certain training data sets and cost functions described herein (e.g., see detailed description of the methods in FIG. 7 and the example of FIG. 4B).

In the present example, the training of the CNN model is based on input data sets DS1 and DS2. The training data set DS1 comprises, for example, data related to one or more prior layers and/or the current layer of a current substrate being patterned. The training data set DS2 comprises, for example, data related to one or more prior substrates that were patterned before the current substrate.

In an embodiment, e.g., CNN models can be configured to take a substrate map or a part of the substrate map (i.e., a die or field) directly as an image input, while other machine learning models typically convert a map to other low dimensional representation. For example, a dimension refers to a dimension of data set used to train the model. In an example, the low dimensional representation refers to reduced number data points obtained by reducing the original data set. For example, original data set may include 3000 points which can be reduced to 10 data points, e.g., via principal component analysis.

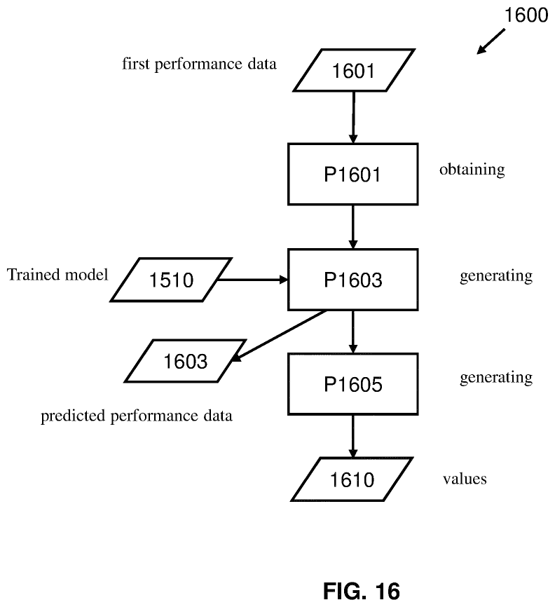

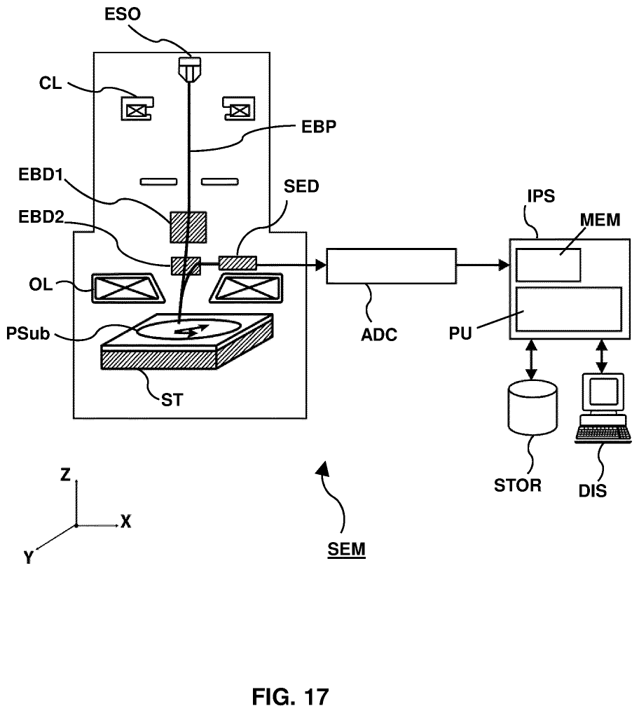

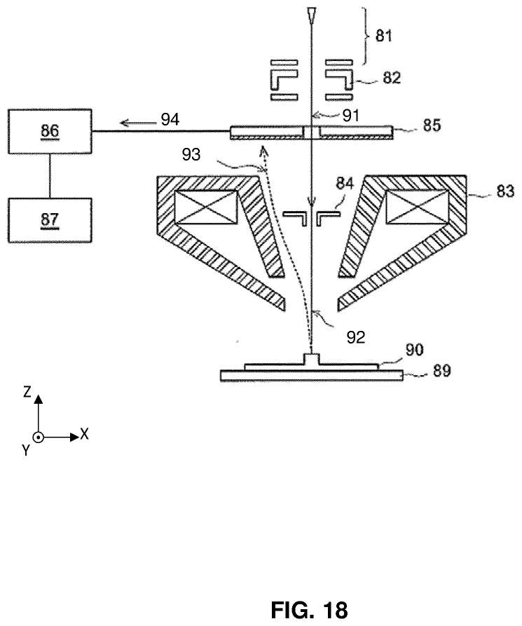

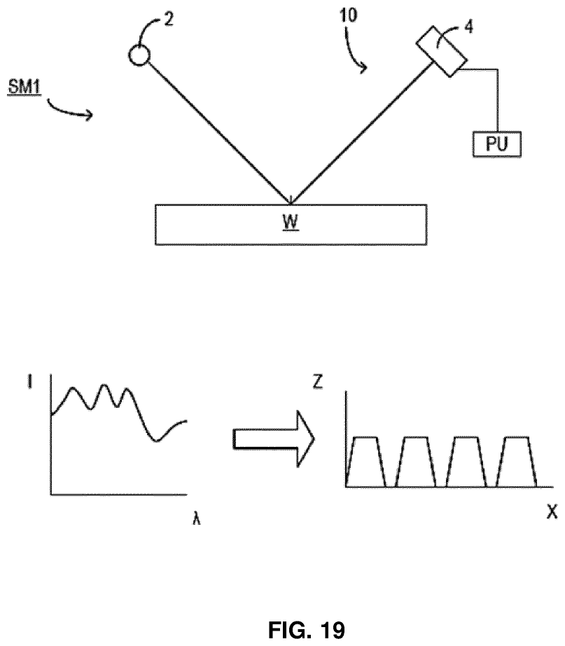

In an embodiment, the example data set DS1 may comprise overlay metrology data associated with previous layers for the current substrate. The overlay metrology data includes, but is not limited to, measured overlay data (or map) and a de-corrected overlay data (or map). In an embodiment, the measured overlay data refers to data obtained after overlay related corrections (e.g., alignment control, level control, focus control, etc.) are applied e.g., via the patterning apparatus. In an embodiment, the de-corrected overlay data refers to overlay data before any overlay corrections are applied e.g., via the patterning apparatus. In an embodiment, the overlay metrology data may be obtained via metrology tools such as optical metrology (see FIG. 19-FIG. 22) or SEM (see FIG. 17 and FIG. 18). In an embodiment, overlay metrology data may be derived based on processing parameters such as discussed in U.S. Patent Application No. 62/462,201 filed on Feb. 22, 2017, which is incorporated herein in its entirety by reference.

Furthermore, the example data set DS1 may comprise alignment metrology data (e.g., AlignMet data in FIG. 4A) from previous layers for the current substrate including, but not limited to, alignment sensor data (not shown), a residual map (see FIG. 4A), a substrate quality map (see FIG. 4A), and/or color2color difference map (see c-to-c map in FIG. 4A).

Furthermore, the example data set DS1 may comprise Leveling metrology data (e.g., LvlMet data in FIG. 4A) from previous layers for the current substrate including, but is not limited to, data from a substrate height map (not shown) and/or Z2xy map (see FIG. 4A).

Furthermore, the example data set DS1 may comprise Context information (e.g., shown in FIG. 4A) of previous layers for the current substrate including, but not limited to, a lag time (an example of a continuous variable) associated with a process (e.g., resist development) performed within a tool (e.g., resist development tool), chuck identifier data (an example of a categorical variable), chamber identifier data (another example of a categorical variable), chamber FP data (e.g., EC1, EC2, . . . ECn show in FIG. 4A) and/or other information that may relate to the overlay error.

In an embodiment, the example data set DS2 comprise overlay metrology data from previous lots. In an example, the metrology data is represented as a map generated based on the metrology data. For example, data from a plurality of substrate may be collected and a single map may be generated by overlapping and/or averaging data across the substrate. In FIG. 4A, overlay metrology data (e.g., OVL-prior) is obtained by taking an exponential moving average of overlay data associated with previously patterned substrates. The overlay metrology data (e.g., OVL-prior) is represented as a map or an overlay fingerprint that illustrates relatively high overlay error at a left edge compared to other locations of the substrate.

In an embodiment, the training data set can be further extended to include scanner related data. The scanner data (an example of first data set in method 700) may contain information associated with all layers up to the current layer (the current layer may be included) for the current substrate. For different layers the same substrate may be exposed by different scanners (e.g., as discussed with respect to FIGS. 2 and 3) and processed by different processing tools (e.g., as discussed with respect to FIGS. 2 and 3). So the scanner data is not necessarily limited to only one scanner or one processing tool. Information related to all the scanners and processing tools used in patterning process may be used for training the model.

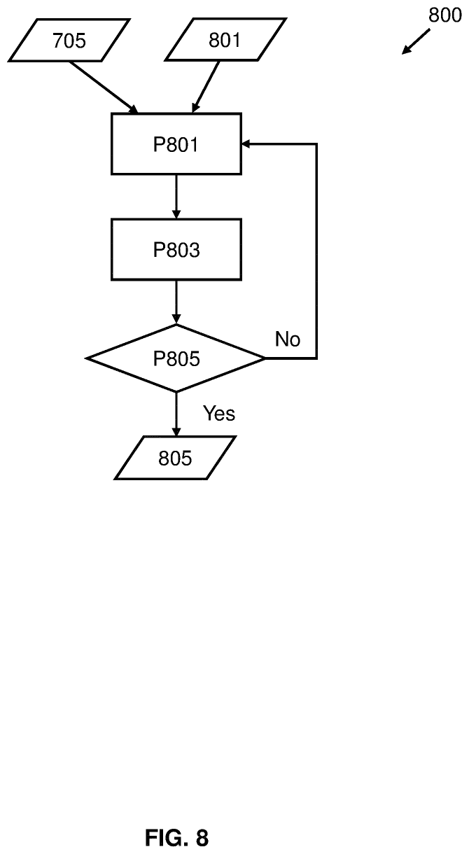

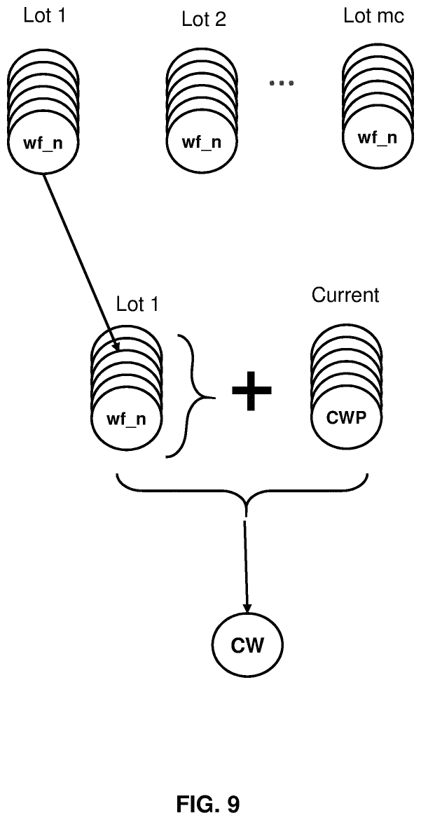

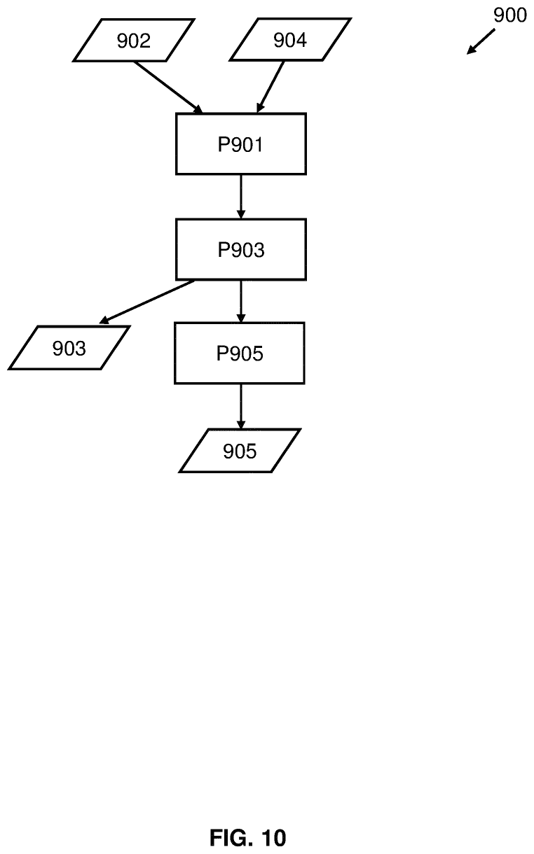

For example, the scanner data includes, but not limited to, tool information (e.g., scanner id, chuck id), raw measurements (e.g., from a measurement software, sensors, etc.) and key performance indicators related to overlay error, and reported metrology data (e.g., alignment data, leveling data, etc.). The training data set can also include fabrication related data (also referred as fabrication context information) that includes, but not limited to, processing tools (e.g., etch chamber, chemical mechanical polishing tool used to polish a substrate, etc.), overlay measurement tools (e.g., optical tool shown in FIGS. 11-14, SEM shown FIGS. 9-10), CD metrology tool (e.g., any tool used to measure CD of a feature such as SEM shown FIGS. 9-10), processing tool related information (e.g., chamber id), raw measurements (e.g., RF time which is an example of a lag time associated with processing of a substrate), reported metrology (e.g., CD and Overlay etc.), and/or continuous and categorical variable information

Furthermore, the training data set may include derived data (e.g., based on scanner data and the fabrication context information). For example, Z2xy, a computation metrology map (e.g., provided by computational metrology tool) related to, for example, a process variable or a performance indicator, scanner performance detection, derived chamber fingerprints (e.g., unique data patterns associated with a variable (e.g., overlay, alignment, etc.) of a particular tool used in the patterning process) using advanced decomposition algorithms (e.g., as discussed in U.S. patent application No. 62/462,201 filed on Feb. 22, 2019, which is incorporated herein in its entirety by reference).

In an embodiment, SPD data refers to a scanner performance detection, for example, via simulation software that determines performance (e.g., key performance parameters) related to a scanner used for imaging the given substrates. The scanner performance detection is further discussed in detail in EP application number EP19155660.4, filed on Feb. 6, 2019, which is incorporated herein in its entirety by reference.

In an embodiment, Z2xy refers to overlay contribution associated with a substrate height map. The substrate height map can be obtained, for example, from the levelling sensor of the lithographic apparatus. A difference can be found for the substrate height maps for two pattern transfers and then the difference can be converted to an overlay value and thus the overlay contribution. For example, the Z height difference can be turned into X and/or Y displacements by considering the height difference as a warpage or bend of the substrate and using first principles to calculate the X and/or Y displacements (e.g., the displacement can be the variation in Z versus the variation in X or Y times half the thickness of the substrate in, e.g., a clamped region of the substrate or the displacement can be calculated using Kirchhoff-Love plate theory in, e.g., an unclamped region of the substrate). In an embodiment, the translation of the height to the overlay contribution can be determined through simulation, mathematical modelling and/or experimentation. So, by using such substrate height information per pattern transfer, the overlay impact due to a focus or chuck spot can be observed and accounted for. In an embodiment, such overlay contribution may be removed from the overlay map during a pre-processing step as discussed herein. A detailed discussed overlay contributions associated with a substrate height map or other variables related to patterning process is provided in U.S. Patent Application No. 62/462,201 filed on Feb. 22, 2017, which is incorporated herein in its entirety by reference.

In an embodiment, the training data may be pre-processed to improve a quality of the data, extract most relevant data, remove certain data, etc. for improving predictions related to overlay. For example, different preprocessing methods can be applied on substrate maps to remove irrelevant/unwanted or extract more useful information from different substrate maps. For example, for overlay maps (either as input or training output), chuck based average fingerprint map (or a chuck based moving average fingerprint map) may be removed so that the remaining map can capture overlay variation better. As another example, modeling (e.g., based on process variables or processing parameters) on overlay substrate maps may be performed to retrieve correctable components of a total fingerprint of a process variable of interest. For example, a total fingerprint of the overlay includes overlay contributions from different process variables, each such contributions are added to generate the total fingerprint. Then, a correctable overlay component (e.g., correctable via alignment, leveling, etc.) included in a total overlay fingerprint may be extract. The same concept of modeling can be applied to other substrate maps related to alignment and leveling of the substrate. Additional example of removing or extracting relevant data based on processing variable of the patterning process is discussed in more detail, for example, in the incorporated U.S. patent application No. 62/462,201.

In general, the training data set may include all information associated with the current substrate from all processing layers (including current layer) and previous lots can be used in computation fingerprint (cFP) modeling. In some cases, in a feedforward application, all the information may not be available in a timely manner such as certain scanner information (e.g., alignment and leveling of a current layer) due to scanner throughput limitation. However, as metrology related technology improves such data may be available in real-time, in which case, all the real-time scanner information may also be used for training the model to make more accurate predictions.

In the present disclosure, the training data set may comprise all the inputs (e.g., data within DS1, DS2 and measured overlay data) or any combination of inputs (e.g., selected data from DS1, selected data from DS2, etc.). For example, all the data sets mentioned herein may be used as inputs to build a complex machine learning model as discussed herein. As another example, selected subset or subsets of inputs from the above list may be used to build the model (also referred as cFP model). The selection of the subset(s) may be based on certain features. The feature selection can be based on domain knowledge or purely data driven by using any existing feature selection algorithm in a machine learning field.

As for the output, the model can predict the de-corrected overlay data from the current layer for the current substrate, which is later used for controlling various processes of the patterning process (e.g., as discussed in the incorporated by reference U.S. applications US2013230797A1 and US2012008127A1) to improve the yield of the patterning process, such as defects due to overlay error related to very small features (e.g., less than 10 nm).

As mentioned earlier, the input data is used to generate, via the model a predicted output. The goal of the training process is to predict an accurate output data. In an embodiment, such accurate predictions are achieved by reducing an error between predicted output data and a ground truth (or reference data). For example, FIG. 4B illustrates the difference between a predicted de-corrected overlay data PDOD (e.g., a map) and a measured de-corrected overlay data MDOD (an example of a ground truth or a reference map). In the present example, the predicted de-corrected overlay data PDOD is associated with a current layer of the substrate being processed. Such predicted data PDOD is obtained, via executing the model (e.g., CNN in FIG. 4A) using the inputs DS1 and DS2, before any corrections are applied to the current layer. Similarly, the measured data MDOD is obtained via a metrology tool before any corrections are applied to the current layer. If the predictions of the model (e.g., CNN in FIG. 4A) are accurate, then the difference DIFF should very close to zero, and ideally be zero.

As the training process is an iterative process, a first prediction of the CNN model with initial weights may be far-off from zero. However, progressively, the values of the weights (e.g., w11, w12, w13, . . . , w1n, . . . , wnm) of the CNN model can be adjusted (e.g., using a gradient decent method) to reduce the difference DIFF. In an embodiment, the training stops when the difference DIFF is minimized Then, the CNN model characterized by the finalized weight values is considered a trained model. The trained model can be used to predict overlay data for any design layout being printed on a current layer of the current substrate. Based on the predicted overlay data, adjustments can be made, in real-time (e.g., in high volume manufacturing HVM) environment, so that an overlay error associated with a design layout, as well as the yield of the patterning process is improved.

In an embodiment, different cost functions may be used for training the model that results in improved trained model. In the present disclosure, the cost function is independent of the model type (e.g., a point-level model or a substrate-level model). Depending on a type of model being trained, appropriate conversions may be applied, so that any cost function can be used with any model. For example, the conversions may be related for converting point-level data to substrate level data or vice versa so that components of the cost function are in the same units or dimensions (e.g., 1D point-level or 2D map).

In an embodiment, the cost functions may be: (i) a first function (CF1) or a mean n-order error (e.g. MSE is a mean squared error), (ii) a second function or a mean 3sigma (M3S or CF2), or (iii) an on product overlay error. The cost function may be applied to both the point-level model or the substrate-level model as discussed in detail with respect to FIG. 7 below.

In an embodiment, the first function (CF1) or the mean n-order error (or CF1) may be calculated as CF1=mean(sum[|pred-reference|\hat{ }n]), where pred is the predicted data and the reference is the reference data; and the mean is based on an absolute difference between the predicted data and the reference data. The predicted data and the reference data can be either overlay values associated with the given point (e.g., overlay marker) on the given substrates, or projection coefficients (also referred as bases coefficients) associated with the given substrates.

In embodiment, the second function or the mean 3sigma (M3S) may be calculated as: CF2=abs(mean)+3*std, where abs(mean) is an absolute mean, and 3*std is a 3 times of a standard deviation obtained based the difference between the predicted de-corrected overlay data and the reference data, the predicted data are overlay values associated the given points on given substrates.

In an embodiment, OPO (or CF3) can be defined as: CF3=abs(M3S)+1.96*std(M3S), where the mean and the standard deviation of the M3S is computed using the predicted data are overlay values associated with a series of given substrates.

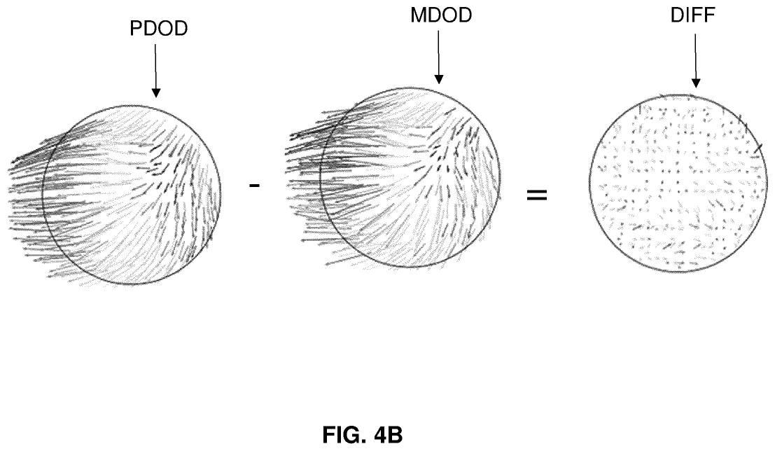

FIG. 5 illustrates example point-level data used to train the point-level model. In an embodiment, a point-level model may be model 1 and/or model 2, where model 1 (e.g., cFPx model) may be configured to predict a de-corrected overlay fingerprint in an x-direction, and model 2 (e.g., cFPy model) may be configured to predict a de-corrected overlay fingerprint in a y-direction. In an embodiment, a single model that predicts overlay in x and y direction at the same time may be determined.

In FIG. 5, each measured marker on a substrate becomes a data sample source, which provides various measurement values (overlay, alignment, leveling, etc. provided in the chart), as discussed herein, at a given position for one of the prior layers of the current substrate. For example, a location P1 corresponding to an overlay marker is associated with different data elements such as a chuck id, measured overlay, de-corrected overlay, alignment system residual, and alignment quality. In the present example chart, the measured overlay measure_ovl (e.g., obtained via a metrology tool e.g., in FIG. 19-FIG. 22) captures an overlay in x-direction and y-direction of a prior layer (e.g., layer 1) of the substrate. The de-corrected overlay DCOvl is for previous layers of a current substrate being patterned. The DCOvl data can be obtained from metrology tool and further used as an input for training the model (e.g., CNN model in FIG. 4A). Furthermore, the alignment system residual may include residual alignment values obtained via different colored-lasers employed by the alignment system. Also, color-to-color map may be obtained based on a difference in diffraction pattern obtained from different colored-lasers. Similar set of information can be obtained for other previous layers, for example, layers 2-4.

In the present example, one training data sample or data element (chart at the left in FIG. 5) at P1 has 81 dimensions (e.g., 20*4+1), where 20 data values are from the measured overlay, the de-corrected overlay, the alignment system residual, and the alignment quality features for one layer; 4 is the number of prior layers of the given substrate, and 1 refers to the chuck id. Thus, P1 provides one data sample comprising 81 dimensions (or data values) to predict one overlay value. If this substrate has 300 markers, then the training data would include 300 such data samples or 300*81 data values.

In an embodiment, training a point-level model (e.g., trained based on point-level data) may involve aligning a grid of substrate maps from different metrology tools and also different layers. Such aligning of the grids may be performed via modeling and interpolation of data with respect to a common grid. In an embodiment, the substrate-level information (e.g., chuck id, RF time, etc.) are shared (i.e., the same) for all points within this substrate. The point-level model may use all information available at the location P1 to predict the overlay value at the location P1. Such an approach can help to enlarge data volume, but might be oversimplified as it treats all points independently.

In an embodiment, the point-level model may be trained based on any of the cost function described herein. For example, the cost function can be the first function of 2nd order, also called a mean squared error (MSE), to determine values of model parameters characterizing the point-level model.

In an embodiment, using the point-level data one can predict an overlay substrate map based on data set associated with each given point on the given substrate. The predicted overlay map can be projected to a set of basis functions (e.g., linear, quadratic, Zernike polynomials, etc.) to obtain projection coefficients (or basis coefficients). The projection coefficients can be used in calculating a cost function based on the difference between the predicted coefficients and ground truth coefficients, where the ground truth coefficients are obtained by projecting the measured de-corrected overlay data to the same set of basis function. Such model fitting computation is differentiable and thus can be optimized using, for example, a standard gradient based method.

In another example, where a training data set is presented at the substrate-level (e.g., an entire substrate, as opposed to a single point on the substrate), the trained model may be referred as a substrate-level model (not illustrated). In an embodiment, a given substrate may be associated with a plurality of substrate maps such as an alignment map, a leveling map, and/or measured overlay map, for example. In a substrate-level model, each substrate becomes a data sample source, in which each associated map (e.g., alignment map, leveling map, overlay map, etc.) is projected on to a set of basis functions to obtain its coefficients as a numerical representation for the projected map. In an embodiment, the projection map can be used either as input or output for the substrate-level model. In an embodiment, the basis functions can be principal component analysis basis function, Zernike polynomial, or other more complicated overlay model including basis functions that contain both inter-field and intra-field function components. In an embodiment, the substrate-level information (e.g., chuck id, RF time, etc.) may also be encoded and then used as additional inputs for determining the substrate level model. Again, any cost function discussed above may be used to determine the values of the model parameters associated with the substrate-level model.

For example, the cost function can be the on product overlay (OPO). To determine OPO, first, a set of projection coefficients are be determined by applying the substrate-level model using input data (in appropriate formats) associated with the current substrate of interest. Then, an overlay map may be re-constructed based on the predicted coefficients. Then, the cost function may be calculated, for example, based on the difference between the re-constructed overlay map and ground truth map. Further, a standard gradient based method may be used to determine optimized values of the cFP model parameters that result in best predicted results (e.g., very close to or equal to ground truth map).

In an embodiment, the projection of each of the plurality of substrate maps may be performed to reduce the dimensionality of the data. For example, for a substrate there are a plurality of substrate maps (e.g., an overlay map, an alignment map, a leveling map, etc.) and each substrate map includes a plurality of data points (e.g., 300). Then, for example, assuming there are 10 substrate maps, each having 300 data points, then the total dimensionality of the data will be 3000. Hence, to reduce the dimensionality, each substrate map may be reconfigured using basis function, e.g., PCA resulting in projecting coefficients associated with each projection map. Such projection maps may be generated for certain substrate level models where handling high dimension data set may be computationally intensive. However, the present disclosure does not limit the substrate model to be determined based on projection coefficients. For example, a convolutional neural network is capable of handling images (e.g., substrate maps), in which case projection of data on basis function may not be performed.

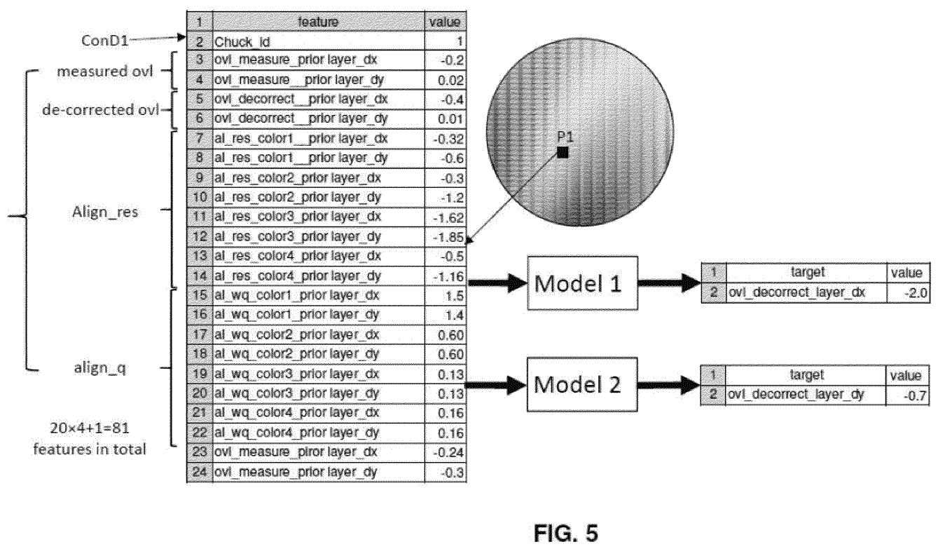

FIG. 6 illustrates an example where decomposition of an OVL map based on basis function related to both inter-filed and intra-filed components. For example, the example overlay map OVL map, in FIG. 6, can be decomposed into Intra-B maps and Inter-B maps. Each map is associated with certain coefficients that are determined via a decomposition method such as PCA, linear regression, or other known methods. The above examples are further explained in methods below.

FIG. 7 is a flow chart of a method 700 for determining a model to predict a de-corrected overlay data associated with a current substrate being patterned. The method 700 involves several procedures as discussed in detail below.

Procedure P701 involves obtaining (i) a first data set 701 associated with one or more prior layers and/or current layer of the current substrate being patterned, (ii) a second data set 702 comprising overlay metrology data associated with one or more prior substrates that were patterned before the current substrate, and (iii) measured de-corrected overlay data 703 associated with the current layer of the current substrate.

In an embodiment, the first data set 701 further comprises scanner data associated with one or more scanners being used for patterning the one or more prior layers and/or the current layer of the current substrate; and fabrication context data associated with processing tools that the current substrate was subjected to before the current layer being patterned or will be subjected to after the current layer is patterned. For different layers the same substrate may be exposed by different scanners and processed by different processing tools, for example, as discussed with respect to FIGS. 2 and 3. So the data does not necessarily associate only to one scanner or one processing tool.

In an embodiment, the scanner data comprises one or more of: a scanner identifier and a scanner chuck identifier associated with the one or more scanners; measurements computed via sensors or a measurement system of the one or more scanners; one or more key performance indicator associated with the one or more scanners and related to an overlay of the current substrate; and metrology data obtained from alignment sensors, leveling sensors, height sensors, and/or other sensors operatively connected to the one or more scanners. In an embodiment, the tools used in of the fabrication comprises one or more of an etch chamber, a chemical mechanical polishing tool, an overlay measurement tool, and/or a CD metrology tool. In an embodiment, an overlay measurement tool e.g., optical tools (e.g., FIGS. 11-14), SEM (e.g., FIGS. 9-10), or other tools configured to measure overlay may be used. In an embodiment, a CD metrology tool e.g., SEM, or other tools may be used to determine CD of feature. Additional tools are further discussed earlier in FIGS. 2, 3, and in U.S. Patent Application 62/834,618 filed on Apr. 16, 2019.

In an embodiment, the first data set 701 (e.g., show in FIGS. 4A and 5) comprises overlay metrology data (e.g., OVL data in FIG. 4A) of the one or more prior layers and/or the current layer of the current substrate, the overlay metrology data comprises: (i) measured overlay data obtained after an overlay correction is applied to the one or more prior layers of the current substrate, and/or (ii) de-corrected overlay data obtained before the overlay correction is applied to the one or more prior layers of the current substrate.

In an embodiment, the first data set 701 comprises alignment metrology data (e.g., AlignMet data in FIG. 4A) of the one or more prior layers and/or the current layer of the current substrate. The alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps (e.g., as discussed with respect to FIG. 4A) obtained via projecting a plurality of colored-laser beams on the substrate, each colored-laser beam reflecting from an alignment mark on the one or more prior layers, the reflected beam generating a diffraction pattern, the color2color difference map being a difference between a first diffraction pattern and a second diffraction pattern, the first diffraction pattern obtained using a first color of the plurality of colored-laser and the second diffraction pattern obtained using a second color of the plurality of colored-laser.

In an embodiment, the first data set 701 comprises leveling metrology data (e.g., LvlMet data in FIG. 4A) of the one or more prior layers and/or the current layer of the current substrate, the leveling metrology data comprises: (i) a substrate height data, and/or (ii) the substrate height data converted to x and y direction displacements.

In an embodiment, the first data set 701 comprises fabrication context information of the one or more prior layers and/or the current layer of the current substrate, the context information comprises: (i) a lag time (e.g., discussed earlier) associated with a process of the patterning process, (ii) a chuck identifier on which a current substrate was mounted, (iii) a chamber identifier indicating a chamber in which the process of the patterning process was performed, and/or (iv) a chamber fingerprint characterizing an overlay contribution of one or more processing parameters (e.g., leveling, alignment, etch rate, etc.) associated with the chamber. In an embodiment, the lag time may be associated with a process or metrology tool used in the process. Example lag time may be associated with resist development, time required to obtain overlay measurement, implementing control commands, etc.

In an embodiment, the first data set 701 further comprises derived data associated with parameters of the patterning process that cause overlay contribution, where the derived data is derived from the scanner data, and/or fabrication context information. For example, the derived data may be obtained as discussed in U.S. patent application 62/462,201; U.S. Patent Application 62/834,618 filed on Apr. 16, 2019; or EP application number EP19155660.4, filed on Feb. 6, 2019, as mentioned earlier.

Procedure P703 involves determining, based on (i) the first data set 701, (ii) the second data set 702, and (iii) the measured data 703, values of a set of model parameters associated with the model such that the model predicts the de-corrected overlay data for the current substrate. In an embodiment, the values of the model parameters are determined such that a cost function is minimized, the cost function comprises a difference between the predicted data and the measured data 703.

In an embodiment, the reducing of the cost function is an iterative process. For example, in procedure P705, a determination is made whether the cost function is reduced. If the cost function is not reduced, then the values of the model parameters (e.g., weights and bias of a CNN, or parameters of associated with a mathematical function) are determined again or an existing values of the model parameters are adjusted (e.g., based on a gradient based method) so that the model predictions output data close to the measured data 703. In an embodiment, the iteration continues until the cost function is minimized For example, the cost function value crosses a desired threshold (e.g., zero, pre-selected value or a value determined via gradient method). Once, the procedure P705 determines the cost function is minimized or no further improvement in cost function is achieved by modifying the values of the model parameters, then training process stops. In an embodiment, the training process can stop after a pre-determined number of iterations. At the end of the training process, a trained model 705 is obtained that has the determined values of the model parameters.

In an embodiment, the model is configured to predict the de-corrected overlay data at a point-level of the current substrate, where a point is a location on the substrate where an overlay marker formed on the current substrate.

In an embodiment, the model is a point-level model, where the values of the model parameter of the point-level model are determined based on the first data set 701, the second data set 702, and the measured de-corrected overlay data 703 that are obtained at a given location on the current substrate having the overlay marker.

In an embodiment, the process of obtaining the first data set 701 the second data set 702, and the measured de-corrected overlay data 703 set at the given location on the current substrate having the overlay marker comprises: representing values of the first data set 701, the second data set 702, and the measured de-corrected overlay data 703 in form a substrate map; aligning, via modeling and/or interpolation, each of the substrate maps; sharing substrate-level information, within the first data set, the second data set, and the measured de-corrected overlay data, respectively, uniformly across the current substrate; and extracting the values of the first data set, the second data set, and the measured de-corrected overlay data, respectively, associated with the given location.

In an embodiment, the substrate-level information comprises at least one of: the chuck identifier, and/or the lag time associated with the processing tool used in the patterning process of the current substrate.

As mentioned earlier, the model may be configured to predict the de-corrected overlay data at a substrate-level. Accordingly, the model is referred to as a substrate-level model. In an embodiment, the values of the model parameters of the substrate-level model are determined based on the projection coefficients associated with maps of the first data set 701 the second data set 702, and the measured de-corrected overlay data 703 across an entire substrate.

In an embodiment, the process of determining of the values of the model parameters of the substrate-model further comprises: generating a plurality of substrate maps using values of the first data set 701, the second data set 702, and the measured de-corrected overlay data 703, respectively, associated with a plurality of prior substrates; projecting each of the plurality of substrate maps to a basis function (e.g., PCA, Zernike or complex intra-field and inter-field function, discussed earlier); determining, based on the projecting, projection coefficients associated with the basis function, the projection coefficients being used to define the substrate model. For example, the projection coefficients can be used as inputs and/or outputs such that the appropriate cost function (e.g., OPO) may be computed. For example, the inputs can be projection coefficients associated with the plurality of substrate maps, and the reference coefficients can be obtained via projection of the measured overlay data 703 on to the basis functions. Then, based on the cost function related to projection coefficients (e.g., mean square error of the absolute difference between predicted projection coefficients and reference coefficients), values of the model parameters may be determined.

In an embodiment, the processing of projecting the substrate maps on the basis function comprises: performing a principal component analysis; or performing a single value decomposition of the substrate maps. In an embodiment, the basis function is a set of Zernike polynomials, and the model parameters are Zernike coefficients, each Zernike coefficient being associated with a respective Zernike polynomial of the set of Zernike polynomials.

As mentioned earlier, projecting the substrate maps on to a basis function may be done to reduce dimensionality of the training data set 701, 702 and 703. However, when the CNN model is used, the projection step may be omitted and raw data 701, 702, and 703 may be used for training the CNN model.

In an embodiment, the model is at least one of: a linear model or a machine learning model. In an embodiment, a linear model is determined based on (i) the first data set associated with at least one selected layer of the current substrate or at least one selected layer of the prior substrates, or (ii) the first data set associated with multiple layers of the current substrate or the prior substrate. In an embodiment the selected layer may be selected based on an overlay contribution from the layer, critical features on the layer, or other overlay related factors. For example, layers capturing maximum overlay contribution, or a layer having most critical features compared to other layers of the given substrate. For example, for the linear model the different inputs may be: 1) de-corrected overlay of one most important previous layer, 2) de-corrected overlays of N selected previous layers of the substrate (e.g., N most important layers such as having critical features), and/or 3) all available input information from both 1 and/or 2. When data from multiple layers is used, the associated feedforward control may be referred as multi-layer feedforward. In other words, multi-layer feedforward implies the control of the patterning process is based on overlay predicted based on multiple layers, thereby capturing more sources of variation which will in turn result in improved control determination.

In an embodiment, the machine learning model may include a plurality of model layers, each model layer being associated with weights and/or biases, the weights and biases being the model parameters. In an embodiment, the machine learning model is at least one of: multi-layer perceptron; random forest; adaptive boosting trees; support vector regression; Gaussian process regression; and/or k-nearest neighbors.

In an embodiment, the machine learning model is an advanced machine learning model including at least one of: a residual neural network (RNN); or a convolutional neural network (CNN). In an embodiment, the RNN model is formulated to include previous layers of the current substrate or the prior substrates as time axis of the RNN.

In an embodiment, for CNN models, the training data set may be the same as before, which can include the first data set 701 and the second data set 702. Also, the output may be the de-corrected overlay map. However, the present CNN model can take substrate map or a portion of the substrate map (i.e., a die or field) directly as the image input, while typically for other machine learning models, a raw data set may need to be converted to other low dimensional representation (e.g., via PCA).

For example, the CNN is trained based on images associated with the current substrate or a portion of the current substrate and/or images associated with the one or more prior substrate, where the images including a predicted image representing a predicted de-corrected overlay data, and a measured image representing the measured overlay data. To clarify, training CNN can also be done using non-image data as additional inputs. For example, the training data set can include chuck id, chamber id, lag time, or other similar inputs.

As mentioned earlier, the present method 700 may employ any cost function for determine values of the model parameter. The cost function is not limited to a particular model (e.g., the point-level model or the substrate model) or model type (e.g., linear, CNN, etc.).

In an embodiment, the cost function is at least one of: a first function, a second function (M3S), or an on product overlay. The example equations were discussed earlier with respect to FIGS. 4A and 4B.

In an embodiment, the first function, where the first mean error is an n-order error is computed using an absolute difference between the predicted data and a reference data, and raising the difference to the n-th order, where the predicted data are overlay values associated with the given points on given substrates or the projection coefficients associated with the given substrates, and the reference data.

In an embodiment, the second function (M3S) computed using a sum of an absolute of mean and 3 times a standard deviation, where the mean and the standard deviation are obtained based the difference between the predicted de-corrected overlay data and the reference data, the predicted data are overlay values associated the given points on the given substrates. For example, if there are 10 substrates, then mean and standard deviation is computed using data associated with the 10 substrates.

In an embodiment, the on product overlay is computed using a sum of mean of the M3S and 1.96 times a standard deviation of the M3S, where the mean and the standard deviation of the M3S is computed using the predicted data are overlay values associated with a series of given substrates. The 1.96 value does not limit the present scope of the disclosure. In another example, other values than 1.96 may be used to determine OPO.

Note, that the second function and OPO is based on point level data. Hence when projection coefficients are available e.g., in case of a substrate model, the substrate maps must be re-constructed using the projection coefficients, then, point-level data can be extracted from such substrate maps to determine the second function and the OPO.

The cost function is minimized using a gradient based method. Such method are well known its implementation details are omitted for brevity.

Uses of the above cost functions can for example be explained in connection with the procedures P703 and P705 for determining the point-level model. These procedures comprise: executing, using data associated with each given location of the plurality of locations on the current substrate, the point-level model using an initial model parameter values to predict the de-corrected overlay data; and determining, based on the predicted de-corrected overlay data and the measured data at the plurality of locations, values of the model parameters such that the first function, the second function, and/or the on product overlay associated with each given location of the plurality of locations on the given substrate is minimized

In an embodiment, determining the point-level model involves first predicting the de-corrected overlay map point-by-point using the point-level model. Then, projecting the substrate map to certain bases to obtain the coefficients, and finally calculating a cost function using, e.g., MSE based on projection coefficients (e.g., difference between projection coefficient related to predicted map and the projection coefficients related to a reference map such as a measured overlay data).

In another example, a substrate model can be characterized by projection coefficients. In this case, the procedures P703 and P705 of determining the substrate-level model may comprises: predicting, using the substrate model, the projection coefficients associated with the basis function; constructing, based on the predicted projection coefficients, an overlay map; calculating the second function or the on product overlay based on the difference between the constructed overlay map and a reference overlay map (e.g., measured overlay map); and determining values of the model parameters such that the second function or the on product overlay is minimized.

In other words, in an embodiment, a substrate-level model (e.g., a non-CNN) whose output is projection coefficients, the projection coefficients may be directly used to determine a cost function. For example, in accordance with one method, we first, predict projection coefficients using the substrate model. Then, calculate the cost function based on this predicted projection coefficients. If the cost function is the first function (e.g., MSE) based on the predicted coefficients and reference coefficients (e.g., obtained by projecting the measured data), then it is straightforward computation. However, if the cost function (e.g., MSE, M3S, OPO) is based on point values of the predicted overlay map and reference map, then the substrate map must be reconstructed using predicted and reference coefficients (i.e., the reverse process of projection).

As mentioned earlier, such projection coefficients are determined to reduce dimensionality of the training data. However, certain model (e.g., a CNN model) may be trained using entire data set or a portion thereof (e.g., one or more dies, field or selected area of the substrate) without performing the projection step.

As discussed herein, the cost function may be used for training the substrate model or the point-level model. Depending on the type of data used to train the model, appropriate data conversions may be applied, so that any cost function can be used with any model. For example, the conversions (e.g., via projecting data on basis function) may be include converting point-level data to substrate level data or vice versa so that components of the cost function are in the same units or dimensions (e.g., 1D point-level or 2D map).

As mentioned earlier, in an embodiment, the first data set, the second data set, and the measured de-corrected overlay data are pre-processed to extract desired information from respective data set. For example, the data sets 701, 702, and 703 may be pre-processed to extract, for example, alignment system model residual data; leveling related residual data; and/or correctable overlay error data. Examples of pre-processing data are discussed in detail in U.S. patent application No. 62/462,201. Hence, such method can supplement the data processing to improve the quality of data and thereby the resulting trained model.

In an embodiment, the first data set 701 or the second data set 702 may be incomplete (e.g., missing some data due to metrology constraints). For example, in an embodiment, the data set 701 or 702 may have some missing overlay metrology data and/or missing context data associated with one or more the prior substrates, or one or more prior layers of the current substrate.

In an embodiment, the missing overlay data is replaced by an average overlay data, where the average overlay data is computed based a lot (or set) of substrates or grouping of the substrate based on the context data. In an example, the grouping may be based on a grouping method such as k-nearest mean. Based on the grouping method, each incoming substrate may be assigned a group id and the average overlay data per group is determined.

In an embodiment, the missing overlay data is replaced with domain knowledge-based overlay data, where the domain knowledge-based overlay data is generated using computational metrology, where the computation metrology comprises an overlay prediction model based on parameters of the patterning process.

In an embodiment, the model (e.g., the point-level model or the substrate-level model) may be structured as a two-level hierarchical model. In an embodiment, a first level of the hierarchical model is configured to predict overlay data using inputs that are always present including data in the first data set and the second data set, and a second level of the hierarchical model predicts overlay refinement to the predicted overlay data of the first level based on inputs that are not always present, the inputs including overlay and certain context data. In an embodiment, for substrates with all inputs present, the sum of predictions from two levels is used as final result. For substrate with missing overlay data, second level predictions are skipped. In an embodiment, the method 700 further involves co-optimizing the two-levels of the hierarchical model.

Procedure P709 involves determining, based on the predicted de-corrected overlay data 707, overlay corrections 709 or control parameters 709′ associated with a lithographic apparatus to improve the overlay performance of the lithographic apparatus. The predicted de-corrected overlay data 707 may be obtained as an output of executing the trained model 705 using inputs related to the current layer of the current substrate being processed. In an embodiment, the predicted overlay data 707 can be provided as an input to process discussed in FIG. 3. In an embodiment, the predicted data 707 may be provided to a correction model such as described in 2013230797A1. Since, the trained model according the present disclosure can provide more accurate overlay predictions, the resulting corrections (e.g., to reduce overlay error), will more accurate thereby improving an existing technology.

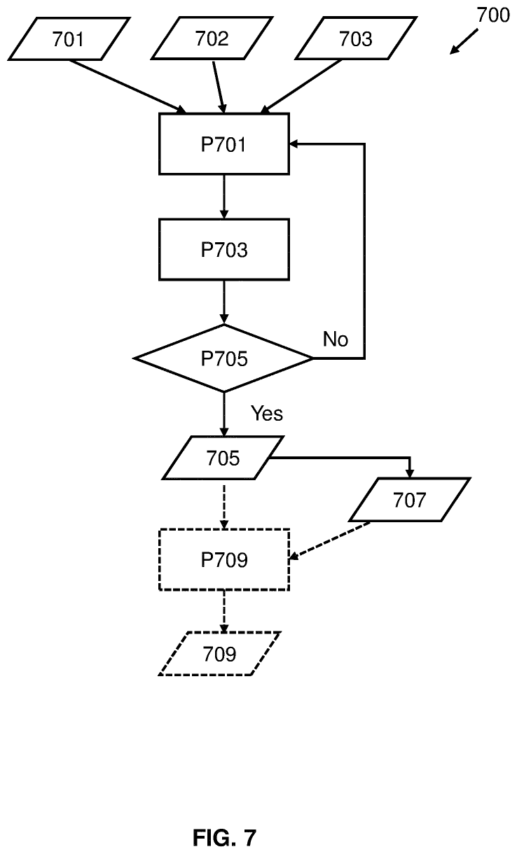

FIG. 8 is a flow chart of a method for updating a trained model to predict a de-corrected overlay data associated with a current substrate being patterned. In an embodiment, the real-time updating may involve obtaining real-time data set 801. In an embodiment, the real-time dataset 801 is similar to data sets 701, 702 and 703 discussed earlier. For example, the real-time dataset 801 is related to similar processing parameters such as scanner data, and context data discussed earlier only that the data is real-time, e.g., data obtained within a time window with respect to a current time.

The method 800 in procedure P801 includes obtaining (i) first data set associated with one or more prior layers of a current substrate being patterned, (ii) a second data set comprising overlay metrology data associated with one or more prior substrates that were patterned before the current substrate, and (iii) measured de-corrected overlay data associated with the current substrate.

The method 800 in procedure P803 involves updating, based on the first data set, the second data set, and the measured de-corrected overlay data associated with the current substrate, the trained model 705 such that a cost function associated with the trained model is reduced. In an embodiment, the cost function comprises a difference between a predicted de-corrected overlay data and the measured de-corrected overlay data, the predicted data is obtained via executing the trained model using the first data set and the second data set.

In an embodiment, the updating of the trained model 705 based on the cost function is an iterative process involving procedure P805 (similar to the procedure P705 discussed earlier). The iterative process includes determining values of the cost function and values of the model parameters to be updated so that the cost function is reduced or minimized The cost function used for the updating of the training model 805 may be same as discussed earlier. For example, the cost functions may be the first function, the second function and the OPO.

In an embodiment, the real-time data 801 may comprise missing data including missing overlay metrology data and/or missing context data associated with e.g., one or more prior layers or current layers of the current substrate.

In an embodiment, the missing overlay data is replaced by an average overlay data, where the averaging overlay data is computed based a lot (or set) of substrates or grouping of the substrate based on the context data. In an example, the grouping may be based on a grouping method such as k-nearest mean. Based on the grouping method, each incoming substrate may be assigned a group id and then average per group is determined.

In an embodiment, the missing overlay data is replaced with domain knowledge-based overlay data, where the domain knowledge-based overlay data is generated using computational metrology, where the computation metrology comprises an overlay prediction model based on parameters of the patterning process.

In an embodiment, the trained model (e.g., the point-level model or the substrate-level model) may be structured as a two-level hierarchical model. In an embodiment, a first level of the hierarchical model is configured to predict overlay data using inputs that are always present including data in the first data set and the second data set, and a second level of the hierarchical model predicts overlay refinement to the predicted overlay data of the first level based on inputs that are not always present, the inputs including overlay and certain context data. In an embodiment, for substrates with all inputs present, the sum of predictions from two levels is used as final result. For wafers with missing overlay, second level predictions are skipped. In an embodiment, the method 700 further includes co-optimizing the two-levels of the hierarchical model.

As mentioned earlier, currently, overlay control is based on indexed weighted moving average EWMA approach, where previous lots measurements are combined in weighted average way and then are applied to the next lot: this is feedback control loop. In overlay run-to-run (R2R) control approach, among other contributors, there are two main contributors to overlay errors: scanner and process effects. The scanner contribution varies slowly with respect to process variations. As process variations are of high frequency, applying previous lots process corrections to the next lot may not be a good approach for advanced node wafer fabrication applications and can cause overlay errors being out of specification.

In the present disclosure, referring to FIG. 9, instead of applying the overlay fingerprint that is determined based on EWMA to the next lot, it is proposed to separate the slowly varying signals (e.g., contribution from scanner) and high frequency signals (e.g., process variations from wafer-to-wafer). Then, the slow varying part from historical lots can be combined with a high frequency contribution of to be exposed wafers in the current lot to use as new correction of the wafers of current lot. In an example, the process contribution per wafer can be estimated using a model and the alignment signal of the current substrate. In an example, the machine learning models to determine the process contribution on overlay can be based on various extracted KPIs', e.g. based on PCA scores between alignment KPIs and overlay signal PCA's. Thus, compared to the standard EWMA R2R control, which is based on a previous lot's average overlay (a lot level control), the proposed approach herein is a wafer level control.

An advantage of the proposed wafer level control method is it does not require additional overlay metrology costs compared to the standard R2R control. Another aspect of the method discussed herein is that alignment signals from previous layers can be used to build models to perform overlay feedforward corrections. The advantage of this approach is that all the calculations can be performed outside of the scanner, e.g. by a separate software product, and supply feedforward corrections to the scanner without modifying existing scanner software.

In the example in FIG. 9, performance data can be overlay data obtained from a previous lot (e.g., Lot1, Lot2, . . . Lotm), each lot includes a plurality of wafers (e.g., n number of wafers). The performance data can be further corrected by removing a process induced overlay fingerprint from the overlay data. In an embodiment, the process induced overlay fingerprints are recognized based on e.g., time analysis of previous lot data, a library of available processing fingerprints, etc.

In an example, the EWMA overlay finger print or historical data based overlay finger print may indicate an average overlay of Lot1 is 0.5 nm. For a current lot, each wafer includes overlay variation across the wafer due to process induced overlay. For example, a first wafer of a current lot has an overlay value (e.g., CWP) of 0.1 nm, a second wafer second has an overlay value 0.2 nm, a third has an overlay value of 0.3 nm, and so on. Then, the correction to be applied to the current wafer (e.g., a first wafer) is based on a total overlay value of 0.6 nm (i.e., 0.5+0.1). Similarly, for the second wafer, overlay correction is based on 0.7 nm (i.e., 0.5+0.2) and so on. So every wafer in the current lot will be corrected based on a different overlay value based on historic overlay and process induced overlay of a current wafer overlay value. In an embodiment, the overlay corrections involve adjustment of the lithography process so that an overlay error in a current wafer is reduced.

In an embodiment, a model (e.g., a machine learning model) is trained to predict a process induced overlay fingerprint based on alignment data. For example, color2color fingerprints are modeled to historically measured overlay data to train the model.

In an embodiment, the trained model is employed to predict overlay error CWP induced by a process or a tool used in the process. Then, for a current wafer CW to be exposed or patterned, the overlay error from a previous lot (e.g., Lot1) is combined with the predicted overlay error CWP related to the process using the alignment data of the wafer to derive a better process correction for the current wafer CW, feedback (overlay previous lot) and feedforward (alignment of the current wafer) are combined to derive an optimal overlay correction for the current wafer CW. For example, such optimal overlay correction results in 0.3 nm OPO improvement. The proposed method for overlay corrections is further discussed in detail below.

FIG. 10 is a flow chart for a method 900 of determining overlay corrections for a current substrate to be patterned. The method includes, for example, procedures P901-P905 further discussed below.

Procedure P901 includes obtaining (i) performance data 902 associated with previously patterned substrates, and (ii) metrology data 904 related to the current substrate to be patterned. In an embodiment, the performance data 902 comprises overlay error data of the previously patterned substrates. In an embodiment, the performance data 902 is an average overlay error value obtained by averaging the overlay error values associated with the previously patterned substrates. For example, an average overlay error from the previous lot can be 0.5 nm. In an embodiment, the performance data 902 is specific to each tool used in the semiconductor manufacturing process. For example, overlay data of the lot processed by the same tool (e.g., a scanner, an etcher, etc.) as the current lot is used.

In an embodiment, the metrology data 904 includes alignment metrology data and leveling metrology data associated with the current substrate. In an embodiment, the alignment metrology data comprises: (i) alignment sensor data, (ii) residual map (e.g., uncorrectable alignment map calculated as a difference between alignment and what scanner can correct) generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on layers of the current substrate, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser. In an embodiment, the leveling metrology data comprises: (i) a substrate height data, and/or (ii) the substrate height data converted to x and y direction displacements.

Procedure P903 includes executing, an overlay prediction model using the metrology data 904 related to the current substrate, to predict overlay error 903 induced by a tool used in a patterning process of the current substrate. In an embodiment, the overlay prediction model is configured to predict overlay error 903 induced by each tool used in the patterning process to the current substrate. In an embodiment, the tool used in the patterning process can be one or more of an etching apparatus; a lithographic apparatus; a chemical mechanical polishing apparatus, or a combination thereof. Example set of the patterning process is discussed with respect to FIG. 2. Accordingly, the predicted overlay error 903 comprises the overlay error induced by the etching apparatus, the lithographic apparatus, the chemical mechanical polishing apparatus, or a combination thereof.

In an embodiment, the overlay prediction model is obtained via: performing (i) a first principal component analysis (PCA) using alignment data related to the previously patterned substrates or test substrates, and (ii) a second PCA using overlay error data related to the previously patterned substrate or the test substrates; and establishing a correlation between components of the first PCA and components of the second PCA.

In an embodiment, the first PCA of the alignment data generates a first set of principal components that explain variations in the alignment data, wherein the first set of principal components include a first set of basis functions and scores associated therewith.

In an embodiment, the second PCA of the overlay error data generates a second set of principal components that explain variations in the overlay error data, wherein the second set of principal components include a second set of basis functions and scores associated therewith.

In an embodiment, one or more principal components of the second set of principal components explain overlay error induced by a particular process or a particular tool of the patterning process.

In an embodiment, the correlation between the first principal components and the second principal components converts the alignment data of the current substrate to the predicted overlay error 903 data of the current substrate. In an embodiment, the predicted overlay error 903 data is associated with a particular process that the current substrate will be subjected.

FIG. 11 illustrates an example PCA performed using the alignment data and overlay data to further build an example overlay prediction model 905. In this example, the alignment data and overlay data may be collected, for example, from 200 training wafers. Using the alignment data of each wafer, an alignment wafer map may be generated for each wafer. Similarly, an overlay map may be generated for each wafer using the overlay data. Further, a principal component analysis (PCA) is performed using the alignment data to generate first set of principal components that explain the variations in the alignment data of each wafer. Similarly, another PCA is performed using the overlay data to generate a second set of principal components that explain the variations in the overlay data of each wafer. Further, a model is trained to map the principal components of alignment data and the principal components of the overlay data. In an embodiment, PCA space is a linear combination of selected basis functions, e.g., first set of basis functions for alignment PCAs and a second set of basis functions for overlay PCAs.

In an embodiment, the reason for mapping a principal component space of alignment data to a principal component space of the overlay data is a point-point mapping of alignment data to overlay data may not be possible. For example, there may be only 20 alignments data points throughout a wafer, while there may be more overlay data points (e.g., 300 overlay points) for the same wafer. So it's very difficult to directly map e.g., 20 numbers of alignment data points to 300 numbers overlay data points. Hence, a different space, which is PC space in this case, is used for mapping or correlation between different data sets.

In an embodiment, “m” is number of principle components may be selected that explain e.g., 95% of the variation in e.g. the alignment data. For example, 95% variation is explained by 10 Principal Components (PC's) where each PC has a score associated therewith. In other words, the PC's associated with the 10 highest scores are selected. In an embodiment, such scores for “m” selected PC's are represented in a matrix, as shown on left side in FIG. 11. In this matrix, each row represents a wafer, and “m” columns represents scores of “m” selected PC's. Thus, in an example, 200×10 matrix including score values (e.g., represented by *) can be formed.

Similarly, a matrix PC_{OV} corresponding to selected overlay PCs can be formed. For example, the selected overlay PC's can be one that explains most variation in the overlay data for a particular wafer. In the present example, matrix PC_{OV} includes a single column and rows same as used in alignment PCs (on left). In an embodiment, a single column indicates a score associated with a single selected basis function of the overlay PC for each wafer.

In an embodiment, in overlay analysis, when these overlay PC fingerprints are determined, in most cases these fingerprints are associated with different processes. Hence, in an embodiment, depending on the process being performed on the substrate, a corresponding overlay fingerprint can be chosen by selecting the appropriate basis function. For example, there may be one overlay PC which is specific for an etching process. So, if one captures the overlay fingerprint related to the etching process, correction related to the etching process or etch induced process overlay can be performed.

Furthermore, based on the alignment PCs and the overlay PCs, the model 905 can be trained to map e.g., 10 alignment PCs scores to a single overlay PC score. In an embodiment, for each OV PCA score a different model may be available, e.g., a first model for mapping first alignment PC to a first overlay PC , a second model for mapping a second alignment PC to a second overlay PC. After training, the model 905 can predict an overlay score based on whatever alignment data of a particular wafer is input. Further, the predicted overlay score can be multiplied with the respective overlay PC basis function to get the overlay value of that particular wafer. Another aspect of building the model involves building a model using multiple scanners. Then, this model can be shared between different scanners.

Procedure P905 includes determining, based on the performance data 902 and the predicted overlay error 903, overlay corrections 905 to be applied to another tool, at which the current substrate will be processed, to compensate for the overlay error induced by the tool. In an embodiment, the tool may be a processing tool (e.g., etcher/deposition) and another tool may be a scanner, so a scanner is configured to correct overlay error introduced by an etcher. For example, the predicted overlay error 903 may be induced by an etching apparatus. Hence, the combined overlay error includes error overlay 903. In this example, the overlay correction 905 (e.g., substrate level adjustment) applied at a scanner to correct for the overlay error including the overlay error 903 induced by the etching apparatus. In an embodiment, the substrate adjustments includes orientation of a substrate table on which the current substrate is mounted; and/or leveling of the substrate table.

In an embodiment, the determining of the overlay corrections includes combining the performance data 902 and the predicted overlay error 903 associated with the tool; and determining substrate adjustments that minimizes the combined overlay error at the another tool being used on the current substrate. For example, as shown in FIG. 9, the predicted overlay error CWP is combined with the overlay error from previously processed Lot1.

In an embodiment, there is provided a system for overlay corrections for a current substrate to be patterned. The system includes a semiconductor manufacturing apparatus (e.g., FIGS. 1 and 2); a metrology tool (e.g., discussed in FIG. 2) for capturing metrology data related to the current substrate to be patterned; a processor (e.g., 104) configured to communicate with the metrology tool and/or control (e.g., based on an overlay prediction model) the semiconductor manufacturing apparatus. In an embodiment, the semiconductor manufacturing apparatus used in the patterning process comprises: an etching apparatus; a lithographic apparatus; a chemical mechanical polishing apparatus, or a combination thereof. In an embodiment, the overlay prediction model is configured to predict overlay error induced by each tool used in the patterning process to the current substrate.

The processor is configured to: execute, an overlay prediction model using the metrology data associated with the current substrate, to predict overlay error induced by the semiconductor manufacturing apparatus used in a patterning process of the current substrate; and determine, based on the performance data and the predicted overlay error, overlay corrections to be applied to another tool, at which the current substrate will be processed, to compensate for the overlay error induced by the tool. In an embodiment, the performance data is an average overlay error value obtained by averaging the overlay error values associated with the previously patterned substrates.

In an embodiment, the processor is configured to determine of the overlay corrections by: combining the performance data and the predicted overlay error associated with the semiconductor manufacturing apparatus; and determining substrate adjustments that minimizes the combined overlay error at another semiconductor manufacturing apparatus being used on the current substrate.

In an embodiment, the processor is further configured to obtain the overlay prediction model by: performing (i) a first principal component analysis (PCA) using the alignment data related to the previously patterned substrate or test substrates, and (ii) a second PCA using overlay error data related to the previously patterned substrate or the test substrates; and establishing a correlation between components of the first PCA and components of the second PCA.

In an embodiment, the correlation between first principal components and second principal components converts the alignment data of the current substrate to predicted overlay error data of the current substrate, the predicted overlay error data is associated with a particular process that the current substrate will be subjected.

In an embodiment, the metrology data is obtained from the metrology tool (e.g., sensors). For example, the alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on layers of the current substrate, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser. Another example of metrology data includes leveling metrology data obtained from e.g., sensors discussed in FIG. 2. The leveling metrology data comprises: (i) a substrate height data, and/or (ii) the substrate height data converted to x and y direction displacements.

In an embodiment, the methods (e.g., 900) described herein can be included as instructions in a computer-readable media (e.g., memory). For example, a non-transitory computer-readable media comprising instructions that, when executed by one or more processors, cause operations including obtaining (i) performance data (e.g., 902) associated with previously patterned substrates, and (ii) metrology data (e.g., 904) related to a current substrate to be patterned; executing, an overlay prediction model using the metrology data associated with the current substrate, to predict overlay error (e.g., 903) induced by a tool used in a patterning process of the current substrate; and determining, based on the performance data and the predicted overlay error, overlay corrections to be applied to another tool, at which the current substrate will be processed, to compensate for the overlay error induced by the tool.

In an embodiment, the non-transitory computer-readable media includes the instructions for the determining of the overlay corrections based on combining the performance data and the predicted overlay error associated with the tool; and determining substrate adjustments that minimizes the combined overlay error at another tool being used on the current substrate.

In an embodiment, the non-transitory computer-readable media includes instructions for obtaining the overlay prediction model via performing (i) a first principal component analysis (PCA) using the alignment data related to the previously patterned substrate or test substrates, and (ii) a second PCA using overlay error data related to the previously patterned substrate or the test substrates; and establishing a correlation between components of the first PCA and components of the second PCA.

In an embodiment, the first PCA of the alignment data generates a first set of principal components that explain variations in the alignment data, wherein the first set of principal components include a first set of basis functions and scores associated therewith.

In an embodiment, the second PCA of the overlay error data generates a second set of principal components that explain variations in the overlay error data, wherein the second set of principal components include a second set of basis functions and scores associated therewith.

In an embodiment, the correlation between the first principal components and the second principal components converts the alignment data of the current substrate to predicted overlay error data of the current substrate, the predicted overlay error data is associated with a particular process that the current substrate will be subjected.

In an embodiment, the non-transitory computer-readable media includes instructions for obtaining the metrology data including alignment metrology data and levelling data associated with the current substrate. In an embodiment, the alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on layers of the current substrate, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser. In an embodiment, leveling metrology data of the current substrate includes: (i) a substrate height data, and/or (ii) the substrate height data converted to x and y direction displacements.

In an embodiment, the performance data is an average overlay error value obtained by averaging the overlay error values associated with the previously patterned substrates. In an embodiment, the overlay prediction model is configured to predict overlay error induced by each tool used in the patterning process to the current substrate.

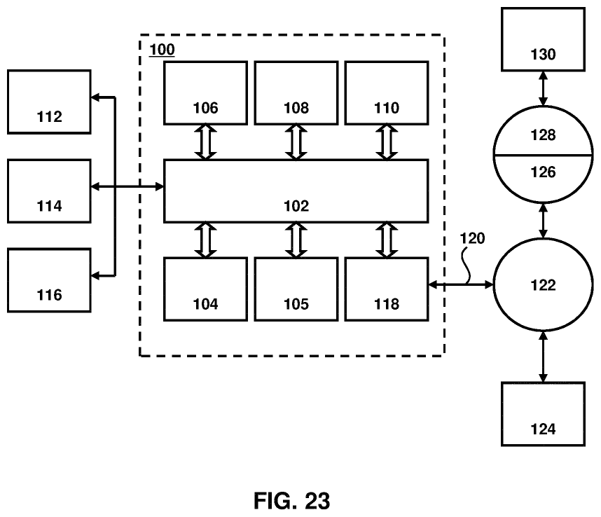

In an embodiment, a computer program product comprising a non-transitory computer readable medium having instructions recorded thereon, the instructions when executed by a computer (e.g., FIG. 23) implementing any of the procedures of the method 700 or 800 discussed above.

In an embodiment, determining training data may involve simulation of the patterning process that can, for example, predict contours, CDs, edge placement (e.g., edge placement error), etc. in the resist and/or etched image. The objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

As discussed earlier, in an embodiment, a model (e.g., a machine learning model) is trained based on process condition data and substrate-level data per patterned substrate. For example, the performance data from alignment sensor, leveling sensor, or overlay determination system/algorithm can be used to train a model to infer overlay of a current layer or future layer to be patterned on the substrate.

In the existing methods, for example, an amount of metrology data required for training a machine learning model can be a burden to users and affect throughput of the process. As a result, users may not measure sufficient patterned substrate for accurately training the model. Measuring large amount of data for training or updating models may be considered too expensive to be used in semiconductor manufacturing.

The present disclosure proposes to train a model based on region (e.g., field) specific data of a patterned substrate. Furthermore, the trained model can be updated in a similar manner using newly available performance data of one or more portions of the patterned substrate. In an embodiment, a substrate-level performance data samples are divided into fields. For example, in a lot of 25 substrates, each substrate may be divided into 110 fields, which will generate 2750 samples for training the model. In an embodiment, the performance data used for training can be from alignment, leveling, overlay, or other performance related parameters or metrics. In an embodiment, the performance data can be of a same layer as a target layer (e.g., a top layer) and/or one or more bottom layers below the target layer. The performance data (e.g., overlay) discussed herein are presented by way of example to explain the concepts and does not limit the scope of the present disclosure.

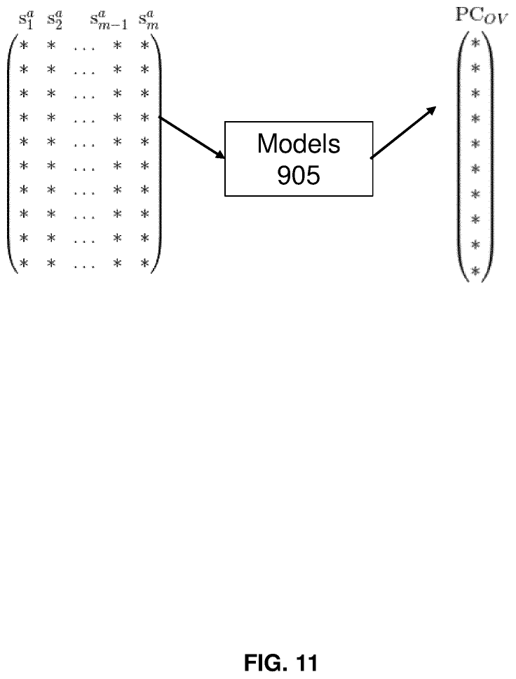

FIG. 12 illustrates example performance data used for training a model 1200. A patterned substrate 1210 is divided into a plurality of portions, e.g., 110 potions P1-P110. The plurality of portions e.g., P1-P110, across a plurality of patterned substrates (e.g., 25 substrates) can be stacked on top of each other. In an example, performance data from 25 patterned substrates with 110 portions per substrate gives 2750 stacked portions that can be used as training data set. In an embodiment, the performance data associated with one or more layers BLS is correlated, via a model 1200, with the performance data associated with a target layer TLS (e.g., a top layer).

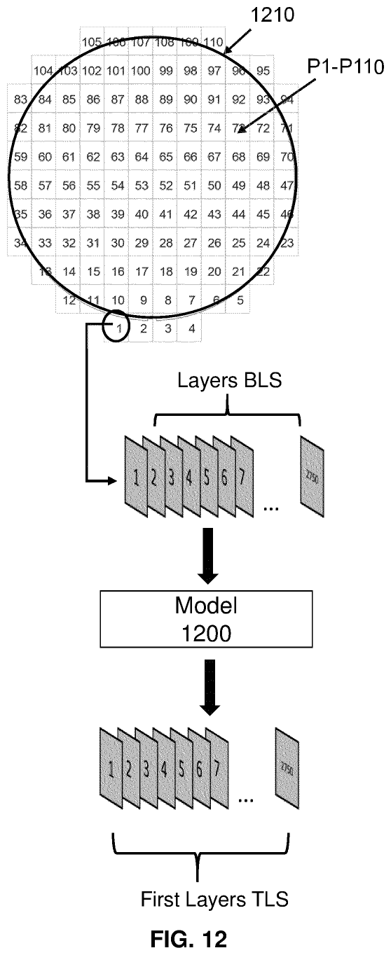

FIG. 13 is a pictorial representation of exemplary overlay data 1300. The overlay data 1300 can be divided into, for example, edge fields (e.g., partial fields P1-P4, P5, P6, P11, P12, and so on in FIG. 12) and full fields (e.g., P7-P10, P14-20, P24-P33, and so on in FIG. 12) on the substrate. The per field overlay data can be further used for training the model (e.g., the model 1200). The trained model can then predict per field performance data for any given input performance data.

In an embodiment, dividing the performance data into one or more portions (e.g., P1-P110) of the patterned substrate provides several advantages. For example, only few patterned substrates or portions of the patterned substrates may be measured. As such, an amount of metrology time may be reduced making the training/updating of the model cost effective. Also, even with reduced measurements, sufficient amount of data can be made available for training the model.

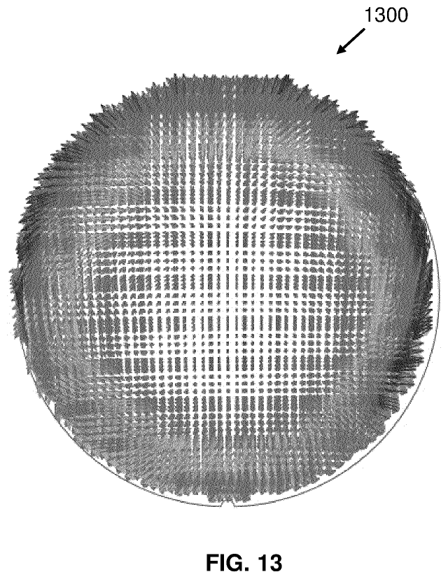

In an embodiment, a model is trained, or updated using available performance data such as overlay (OVL) data related to patterned layers. The OVL data may be obtained by stacking portions such as fields (see FIG. 12) of a substrate. The model receives the OVL data per field associated with one or more previous layers as input. Additionally, other performance data such as alignment, leveling, and context data or other data, as discussed herein, may be used for training the model. In an embodiment, the trained model predicts performance data such as OVL per field of the future layer to be patterned on the substrate. The predicted OVL per field is fed forward (FF) to a lithographic apparatus to optimize e.g., exposure of the future layer per field. An example algorithm employing the predicted OVL per field data to configure a process or apparatus (e.g., lithographic apparatus) associated with patterning is illustrated in FIG. 14.

FIG. 14 is a block diagram illustrating a feedforward (FF) process for controlling a lithographic apparatus. The feedforward process integrates the predicted performance data per field of the present disclosure with an advanced process control (APC) process to determine more accurate adjustments to the lithographic apparatus. The APC determines, for example, corrections based on metrology data of a patterned substrate. An example, APC is discussed in U.S. Pat. No. 9,177,219 B2, which is incorporated herein by reference in its entirety.

In the present example, in FIG. 14, performance data 1410 associated with a first lot of patterned substrate layers L₁1, L₁2, L₁3, and L₁4 is obtained, for example, via a metrology tool or a sensor. The performance data 1410 can be obtained from patterned substrate layers of a prior lot of substrates (e.g., L₁) or a current lot of substrates (e.g., L₂). Furthermore, other performance data 1420 can be obtained from a current substrate being patterned. The current substrate (e.g., 1420) may have patterned layers L₂2, L₂3, and L₂4, while a layer L₂1 is a future layer desired to be patterned on the current substrate. In the present example, the performance data 1420 of a second lot (e.g., L₂) of patterned substrates can be used for verification purposes. In the present example, the performance data 1420 associated with layers L₂2, L₂3 and L₂4 can be obtained (e.g., via sensors or metrology tools) and performance data associated with the future layer (e.g., a top layer L₂1 can be the future layer) is predicted by a trained model 1200. In an embodiment, the performance data 1410 includes, for example, overlay determined between a first layer L₁1 and one or more other layers such as layers L₁2, L₁3, and L₁4. Similarly, the performance data 1420 includes, for example, overlay determined between layers L₂2 and L₂3, and layers L₂2 and L₂4, while overlay data of future layer L₂1 can be predicted using the trained model 1200.

In an embodiment, the performance data (e.g., OVL) of layer L₂1 can be determined as follows. At block 1414, a model 1200 is trained based on the performance data 1410. For example, the model 1200 is trained based on the overlay between layers L₁2 and layers L₁3/L₁4, and target overlay between layers L₁1 and L₁3/L₁4. Further, the trained model 1200 can be executed to determine the performance data of a future layer of a subsequent lot (e.g., L₂). For example, the trained model 1200 predicts overlay between the first layer L₂1 and the other layers L₂2, L₂3, and L₂4.

At block 1412, residual performance data can be computed as a difference between e.g., OVL of layer L₁1 with respect to other layer such as L₂2 and L₂3, respectively, and model predicted OVL at block 1414. In an embodiment, the performance data can be, for example, CD, EPE, OVL in a particular direction such as x and y used during double patenting. In addition, at block 1416, average performance data of the block 1412, the prior lot of substrates can be determined. In an embodiment, the data 1410 and 1420 are de-corrected performance data. In an embodiment, the average performance data, at block 1416, can be obtained from the APC process that models, for example, substrate-level performance data (e.g., overlay) based on measured data (e.g., 1410) of the patterned substrate.

At block 1422, the trained model 1200 (at block 1414) uses data 1420 to determine a correlation between the first layer L₂1 and the other layers L₂2, L₂3, and L₂4 (e.g., which are examples of layers of future lot) to which the data of block 1416 is added.

As mentioned earlier, the trained model 1200 can be applied to the performance data 1420 of the current substrate being patterned to determine the performance data 1422 per field of the future layer L₂1 to be formed on the substrate. For example, performance data of L₂2, L₂3, and L₂4 can be used along with the correlation determined by the trained model 1200 to predict the performance data 1422 of the future layer L₂1. The predicted performance data of the future layer L₂1 is per field data, for example. The predicted data 1422 of L₂1 can be combined with the average data (at block 1416) of prior substrates to determined how a patterned process should be configured to cause the performance data of layer L₂1 to be within a specified performance range upon patterning. Thus, a forward correction can be applied to a patterning apparatus or a process. The forward correction can be applied by adjusting a patterning process based on the predicted performance data of L₂1 and prior de-corrected performance data. For example, the predicted performance data can be used to adjust dose, focus or other parameters of a scanner during imaging of the layer L₂1 on the current substrate. In an embodiment, the predicted overlay data can be used to adjust alignment and leveling of the substrate. In an embodiment, the predicted EPE or CD data can be used to adjust dose and focus of the scanner. The adjusted parameters will cause the layer L₂1 to be formed that has, for example, the performance (e.g., overlay, EPE, CD, etc.) within a specified performance threshold.

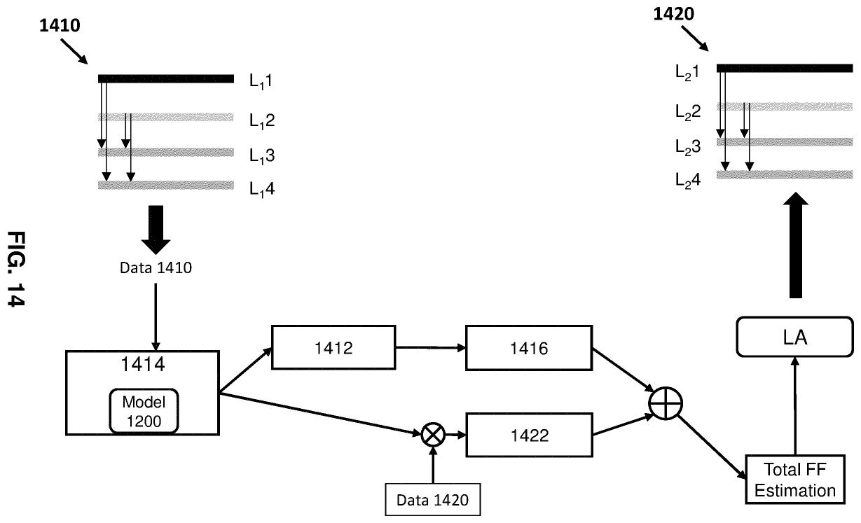

FIG. 15 is a flowchart of a method for training a model to predict performance data for one or more portions of a substrate. In an embodiment, the method 1500 can be implemented as procedures P1501, P1503, and P1505 further described in detail below.

Procedure P1501 includes obtaining performance data 1501 associated with portions of a plurality of patterned substrate layers formed one on top of another. An example of the performance data 1501 per portion of the patterned substrate layers is shown in FIGS. 12 and 13. In an embodiment, the obtaining of the performance data 1501 includes splitting the performance data 1501 according to one or more portions of the substrate (see FIG. 12). In an embodiment, a portion of the plurality of portions of the patterned substrate layers is a field, a sub-field, or a die area of the substrate.

In an embodiment, the first performance data 1501 and the predicted performance data 1503 comprise at least one of: overlay data associated with a given layer of the substrate; alignment data associated with the given layer of the substrate; leveling data associated with the given layer of the substrate; correctable overlay error data (e.g., correctable via alignment, leveling, etc.) associated with the given layer of the substrate, height data of the given layer with respect to one or more bottom layers on the substrate; or other data measured via a sensor, tool, or metrology system discussed herein. For example, the alignment data may comprise orientation or translation of one or more portions of the substrate during the patterning. The alignment data can be captured by, for example, an alignment system, the height and/or levelling data may be obtained by a level sensor, in the lithographic apparatus, as discussed herein. Similarly, other performance data such as leveling and correctable overlay error can be obtained via a level sensor and an overlay measurement system, respectively.

Procedure P1503 includes providing the performance data 1501 of the portions of the patterned substrate layers as input to a base prediction model to obtain predicted performance data 1503 associated with the portions of a first layer of the substrate. In an embodiment, the model is at least one of: a linear model; or a machine learning model. In an embodiment, the machine learning model can be a neural network. For example the machine learning model can be at least one of: multi-layer perceptron; random forest; adaptive boosting trees; support vector regression; Gaussian process regression; k-nearest neighbors; feed forward; recurrent neural network; long/short term memory; gated recurrent; auto encoder; markov chain; Hopfield network; Boltzmann machine; deep belief network, or other versions of a neural network. In an embodiment, the machine learning model is an advanced machine learning model including at least one of: a residual neural network (RNN); a convolutional neural network (CNN); or a deep CNN. In an embodiment, the RNN model is formulated to include input associated with patterned substrate layers of a current lot of substrates or patterned substrate layers of a prior of substrates as time axis. RNN has the ability to model correlations between features in time and in frequency domain. It's a way to stack the inputs. For example, in the RNN, a set of filters is convolved with the input that results in multiple output-maps, one per filter. This is followed by the application of an element-wise activation function, such as the σ (⋅) function. These operations are performed on an input data with two axes, such as a spectrogram (time×frequency).

Procedure P1505 includes using the inputted performance data 1501 associated with the first layer as feedback to update one or more configurations of the base prediction model 1509, wherein the one or more configurations are updated based on a comparison between the inputted performance data 1501 and the predicted performance data 1503 of the first layer. In an embodiment, the performance data 1501 comprises data 1501 used for predictions and data 1501′ which can be real measured data associated with the patterned layer (e.g., layer L₂1 of FIG. 14 after patterning) used for updating model.

After training, the prediction model 1510 gets configured/updated to correlate the performance data 1501 of the first layer with one or more other patterned substrate layers. For example, the trained prediction model 1510 can provide a relationship between different layers. For example, a relationship between performance data of a first layer and a second layer, the first layer and the third layer, the first layer and the fourth layer, and so on. After training the base model 1509, the model is referred as a trained model or a trained prediction model 1510.

In an embodiment, the procedure P1505 discusses an approach for training the base model 1509 to obtain the trained prediction model 1510. The training of the model 1509 is an iterative process. Each iteration includes predicting, via the base prediction model 1509 using the performance data 1501 associated with the portions of the substrate and given model parameter values (e.g., an initial values set by a user), the performance data 1503 associated with the portions of the first layer; comparing the model predicted performance data 1503 associated with the portions of the first layer with the obtained performance data 1501 associated with the portions of the first layer; and adjusting, based on the difference, the given model parameter values of the base model 1509 to cause a difference between the model-predicted performance data 1503 and the obtained performance data 1501 associated with portions of the first layer of the plurality of patterned substrate layers to be within a specified range. In an embodiment, the adjusting of the given model parameter values of the base model 1509 is performed until the difference is minimized

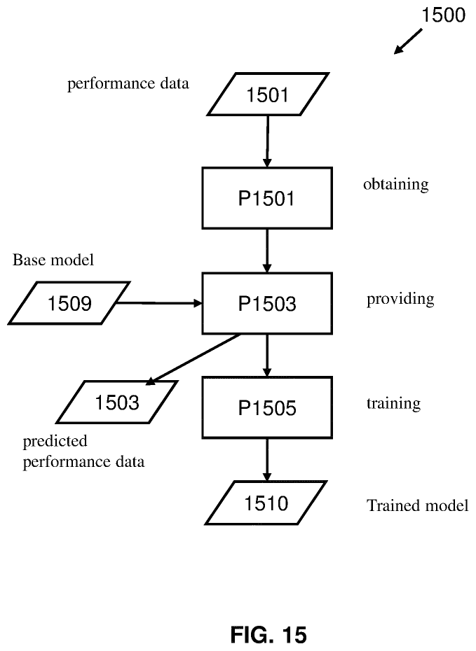

FIG. 16 is a flowchart of a method 1600 for controlling a patterning process or a patterning apparatus based on feedforward estimation of performance data of patterned substrate. Using the method 1600, the performance of future layers of the substrate can be improved, which in turn improves the yield of the patterning process. For example, overlay of future layers can be improved by correcting for estimated overlay using input of an alignment system. For example, a substrate table adjustment system can adjust a substrate orientation, translation, or height during the patterning process. In another example, the performance data can be CD or EPE associated with the features to be imaged on a top layer. In this example, dose, and/or focus of a scanner can be adjusted based on the estimated performance (e.g., CD, EPE) of a future layer to be formed on the substrate. The feedforward method 1600 of controlling or configuring a patterning process is further discussed in detail in procedures P1601, P1603, and P1605 as follows.

Procedure P1601 includes obtaining first performance data 1601 associated with portions of a plurality of patterned substrate layers of a substrate. In an embodiment, the first performance data 1601 includes substrate-level performance data associated with a current lot of patterned substrates. In an embodiment, the first performance data 1601 further comprises substrate-level performance data associated with a previous lot of patterned substrates. In an embodiment, the first performance data 1601 includes performance data associated with a first layer (e.g., a top layer) of the substrate for which the performance is to be inferred; and performance data associated with a second layer (e.g., a bottom layer) of the substrate. The second layer is located below the first layer of the substrate. For example, see FIG. 14, the performance data 1410 associated with layers L₁1-L₁4, or the performance data 1420 associated with layers L₂1-L₂4, where L₂1 can be the performance data to be predicted. In an embodiment, the portions of the patterned substrate layers are aligned. For example, also see portions P1-P110 of a patterned substrate in FIG. 12.

In an embodiment, the first performance data 1601 includes the substrate-level performance data that is divided into portion specific performance data (see FIG. 12). In an embodiment, the first performance data 1601 (and predicted performance data 1603) comprises at least one of: overlay data associated with a given layer of the substrate; alignment data associated with the given layer of the substrate; leveling data associated with the given layer of the substrate; correctable overlay error data associated with the given layer of the substrate, height data of the given layer with respect to one or more bottom layers on the substrate, or other performance related data as discussed herein.

Procedure P1603 includes generating, via the trained model 1510 using the first performance data 1601 as input, predicted performance data 1603 relating to one or more portions of a future layer that will be formed on the substrate. In an embodiment, the portion of the substrate is a field, a sub-field, or a die area of the substrate. For example, the trained model 1510 can be used to predict performance data of one or more portions of the future layer such as layer L₂1 of the performance data 1420, as shown in FIG. 14.

Referring back to FIG. 16, in an embodiment, the trained model 1510 is configured to correlate the first performance data 1601 associated with a first layer with one or more other patterned substrate layers. In an embodiment, the trained model 1510 is at least one of: a linear model; or a machine learning model. In an embodiment, the machine learning model is at least one of: multi-layer perceptron; random forest; adaptive boosting trees; support vector regression; Gaussian process regression; or k-nearest neighbors. In an embodiment, the machine learning model is an advanced machine learning model including at least one of: a residual neural network (RNN); or a convolutional neural network (CNN). In an embodiment, the RNN model is formulated to include data related to the patterned substrate layers as time axis.

Procedure P1605 includes generating, based on the first performance data 1601 associated with the patterned substrate layers and the predicted performance data 1603 associated with the future layer, values 1610 of one or more parameters for controlling a patterning process to cause a second performance data associated with the future layer of the substrate to be within a specified performance range.

In an embodiment, the generating of the values 1610 of the one or more parameters include determining, based on the first performance data 1601, de-corrected performance data associated with the patterned substrate layers; determining, based on the predicted performance data 1603 relating to the one or more portions of the further layer, substrate-level performance data of the future layer; adjusting, based on the substrate-level performance data of the future layer and the de-corrected performance data of the patterned substrate layers, values 1610 of one or more parameters of the patterning process to cause the performance data of the future layer of the substrate to be within the specified performance range after patterning.

In an embodiment, the one or more parameters comprises: dose, focus, alignment of the substrate with respect to a reference, height of the substrate, layer thickness, deposition process parameters, and/or etch process parameters. For example, the predicted overlay of the future layer applied as an intentional overlay bias when patterning the future layer. For example, the overlay bias can be implemented adjusted by orientation of the substrate, translation of the substrate, a height of the substrate, or a combination thereof with respect to a reference position or a target position desired on the substrate. In an embodiment, an estimated overlay per portion of the substrate is computed in method 1600. The correction can be applied per portion of the substrate. Hence, overlay correction can be performed for each die, or field.

In an embodiment, there is provided one or more non-transitory computer-readable media storing a prediction model and instructions that, when executed by one or more processors, provides the prediction model. In an embodiment, the instructions are similar to the method 1600. Example of one or more non-transitory media is discussed with respect to FIG. 23.

In an embodiment, the one or more non-transitory computer-readable media includes instruction where the prediction model is produced by: obtaining performance data associated with portions of a plurality of patterned substrate layers formed one on top of another; providing the performance data of the portions of the patterned substrate layers as input to a base prediction model to obtain predicted performance data associated with the portions of a first layer of the substrate; and using the inputted performance data associated with the first layer as feedback to update one or more configurations of the base prediction model, wherein the one or more configurations are updated based on a comparison between the inputted performance data and the predicted performance data of the first layer. The prediction model is structured to correlate the performance data of the first layer with one or more other patterned substrate layers.

In an embodiment, instructions for obtaining of the performance data includes splitting the performance data according to one or more portions of the substrate.

In an embodiment, the first performance data and the predicted performance data comprise at least one of: overlay data associated with a given layer of the substrate; alignment data associated with the given layer of the substrate; leveling data associated with the given layer of the substrate; correctable overlay error data associated with the given layer of the substrate, or height data of the given layer with respect to one or more bottom layers on the substrate.

In an embodiment, the training of the model is an iterative process. Each iteration includes predicting, via the base prediction model using the performance data associated with the portions and given model parameter values, the performance data associated with the portions of the first layer; comparing the model predicted performance data associated with the portions of the first layer with the obtained performance data associated with the portions of the first layer; adjusting, based on the difference, the given model parameter values of the base model to cause a difference between the model-predicted performance data and the obtained performance data associated with portions of the first layer of the plurality of patterned substrate layers to be within a specified range.

In an embodiment, the adjusting of the given model parameter values of the model is performed until the difference is minimized.

In an embodiment, the model is at least one of: a linear model; or a machine learning model. In an embodiment, the machine learning model is at least one of: multi-layer perceptron; random forest; adaptive boosting trees; support vector regression; Gaussian process regression; or k-nearest neighbors. In an embodiment, the machine learning model is an advanced machine learning model including at least one of: a residual neural network (RNN); or a convolutional neural network (CNN). In an embodiment, the RNN model is formulated to include patterned substrate layers of a current lot of substrates or patterned substrate layers of a prior of substrates as time axis.

In an embodiment, the plurality of portions of the patterned substrate layers are fields, sub-fields, or die areas of the substrate.

In an embodiment, the one or more parameters comprise: dose of a scanner, focus of a scanner, alignment of the substrate with respect to a reference, height of the substrate, layer thickness, deposition process parameters, and/or etch process parameters.

In an embodiment, there is provided a non-transitory computer readable medium having instructions thereon, the instructions when executed by a computer causing the computer to for generating a prediction model. The instructions are similar to the steps of method 1500. For example, the instruction include obtaining first performance data associated with portions of a plurality of patterned substrate layers of a substrate; generate, via a trained model using the first performance data, predicted performance data relating to one or more portions of a future layer that will be formed on the substrate; and generating, based on the first performance data associated with the patterned substrate layers and the predicted performance data associated with the future layer, values of one or more parameters for controlling a patterning process to cause a second performance data associated with the future layer of the substrate to be within a specified performance range.

In an embodiment, the first performance data comprises substrate-level performance data associated with a current lot of patterned substrates. In an embodiment, the first performance data further comprises substrate-level performance data associated with a previous lot of patterned substrates. In an embodiment, the first performance data includes performance data associated with a first layer of the substrate; and another performance data associated with a second layer of the substrate, the second layer being located below the first layer of the substrate.

In an embodiment, the trained model is configured to correlate the first performance data associated with a first layer with one or more other patterned substrate layers. For example, as discussed with respect to FIGS. 12 and 14. As mentioned earlier, in an embodiment, the trained model is at least one of: a linear model; or a machine learning model. In an embodiment, the machine learning model is at least one of: multi-layer perceptron; random forest; adaptive boosting trees; support vector regression; Gaussian process regression; or k-nearest neighbors. In an embodiment, the machine learning model is an advanced machine learning model including at least one of: a residual neural network (RNN); or a convolutional neural network (CNN). In an embodiment, the RNN model is formulated to include data related to the patterned substrate layers as time axis.

In an embodiment, the first performance data and the predicted performance data comprises at least one of: overlay data associated with a given layer of the substrate; alignment data associated with the given layer of the substrate; leveling data associated with the given layer of the substrate; correctable overlay error data associated with the given layer of the substrate, or height data of the given layer with respect to one or more bottom layers on the substrate.

In an embodiment, the portions of the patterned substrate layers are aligned. In an embodiment, the portion of the substrate is a field, a sub-field, or a die area of the substrate. In an embodiment, the first performance data comprising the substrate-level performance data is divided into portion specific performance data.

In an embodiment, instructions to generate values of the one or more parameters includes determine, based on the first performance data, de-corrected performance data associated with the patterned substrate layers; determine, based on the predicted performance data relating to the one or more portions of the further layer, substrate-level performance data of the future layer; adjust, based on the substrate-level performance data of the future layer and the de-corrected performance data of the patterned substrate layers, values of one or more parameters of the patterning process to cause the performance data of the future layer of the substrate to be within the specified performance range after patterning.

In an embodiment, the one or more parameters comprises: dose, focus, alignment of the substrate with respect to a reference, height of the substrate, layer thickness, deposition process parameters, and/or etch process parameters.

In some embodiments, the inspection apparatus may be a scanning electron microscope (SEM) that yields an image of a structure (e.g., some or all the structure of a device) exposed or transferred on the substrate. FIG. 17 depicts an embodiment of a SEM tool. A primary electron beam EBP emitted from an electron source ESO is converged by condenser lens CL and then passes through a beam deflector EBD1, an E x B deflector EBD2, and an objective lens OL to irradiate a substrate PSub on a substrate table ST at a focus.

When the substrate PSub is irradiated with electron beam EBP, secondary electrons are generated from the substrate PSub. The secondary electrons are deflected by the E x B deflector EBD2 and detected by a secondary electron detector SED. A two-dimensional electron beam image can be obtained by detecting the electrons generated from the sample in synchronization with, e.g., two dimensional scanning of the electron beam by beam deflector EBD1 or with repetitive scanning of electron beam EBP by beam deflector EBD1 in an X or Y direction, together with continuous movement of the substrate PSub by the substrate table ST in the other of the X or Y direction.

A signal detected by secondary electron detector SED is converted to a digital signal by an analog/digital (A/D) converter ADC, and the digital signal is sent to an image processing system IPU. In an embodiment, the image processing system IPU may have memory MEM to store all or part of digital images for processing by a processing unit PU. The processing unit PU (e.g., specially designed hardware or a combination of hardware and software) is configured to convert or process the digital images into datasets representative of the digital images. Further, image processing system IPU may have a storage medium STOR configured to store the digital images and corresponding datasets in a reference database. A display device DIS may be connected with the image processing system IPU, so that an operator can conduct necessary operation of the equipment with the help of a graphical user interface.

As noted above, SEM images may be processed to extract contours that describe the edges of objects, representing device structures, in the image. These contours are then quantified via metrics, such as CD. Thus, typically, the images of device structures are compared and quantified via simplistic metrics, such as an edge-to-edge distance (CD) or simple pixel differences between images. Typical contour models that detect the edges of the objects in an image in order to measure CD use image gradients. Indeed, those models rely on strong image gradients. But, in practice, the image typically is noisy and has discontinuous boundaries. Techniques, such as smoothing, adaptive thresholding, edge-detection, erosion, and dilation, may be used to process the results of the image gradient contour models to address noisy and discontinuous images, but will ultimately result in a low-resolution quantification of a high-resolution image. Thus, in most instances, mathematical manipulation of images of device structures to reduce noise and automate edge detection results in loss of resolution of the image, thereby resulting in loss of information. Consequently, the result is a low-resolution quantification that amounts to a simplistic representation of a complicated, high-resolution structure.

So, it is desirable to have a mathematical representation of the structures (e.g., circuit features, alignment mark or metrology target portions (e.g., grating features), etc.) produced or expected to be produced using a patterning process, whether, e.g., the structures are in a latent resist image, in a developed resist image or transferred to a layer on the substrate, e.g., by etching, that can preserve the resolution and yet describe the general shape of the structures. In the context of lithography or other pattering processes, the structure may be a device or a portion thereof that is being manufactured and the images may be SEM images of the structure. In some instances, the structure may be a feature of semiconductor device, e.g., integrated circuit. In this case, the structure may be referred as a pattern or a desired pattern that comprises a plurality of feature of the semiconductor device. In some instances, the structure may be an alignment mark, or a portion thereof (e.g., a grating of the alignment mark), that is used in an alignment measurement process to determine alignment of an object (e.g., a substrate) with another object (e.g., a patterning device) or a metrology target, or a portion thereof (e.g., a grating of the metrology target), that is used to measure a parameter (e.g., overlay, focus, dose, etc.) of the patterning process. In an embodiment, the metrology target is a diffractive grating used to measure, e.g., overlay.

FIG. 18 schematically illustrates a further embodiment of an inspection apparatus. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 17 that uses a probe to inspect a substrate, the electron current in the system of FIG. 18 is significantly larger compared to, e.g., a CD SEM such as depicted in FIG. 17, such that the probe spot is large enough so that the inspection speed can be fast. However, the resolution may not be as high as compared to a CD SEM because of the large probe spot. In an embodiment, the above discussed inspection apparatus may be single beam or a multi-beam apparatus without limiting the scope of the present disclosure.

The SEM images, from, e.g., the system of FIG. 17 and/or FIG. 18, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images.

FIG. 19 depicts an example inspection apparatus (e.g., a scatterometer). It comprises a broadband (white light) radiation projector 2 which projects radiation onto a substrate W. The redirected radiation is passed to a spectrometer detector 4, which measures a spectrum 10 (intensity as a function of wavelength) of the specular reflected radiation, as shown, e.g., in the graph in the lower left. From this data, the structure or profile giving rise to the detected spectrum may be reconstructed by processor PU, e.g. by Rigorous Coupled Wave Analysis and non-linear regression or by comparison with a library of simulated spectra as shown at the bottom right of FIG. 19. In general, for the reconstruction the general form of the structure is known and some variables are assumed from knowledge of the process by which the structure was made, leaving only a few variables of the structure to be determined from the measured data. Such an inspection apparatus may be configured as a normal-incidence inspection apparatus or an oblique-incidence inspection apparatus.

Another inspection apparatus that may be used is shown in FIG. 15. In this device, the radiation emitted by radiation source 2 is collimated using lens system 12 and transmitted through interference filter 13 and polarizer 17, reflected by partially reflecting surface 16 and is focused into a spot S on substrate W via an objective lens 15, which has a high numerical aperture (NA), desirably at least 0.9 or at least 0.95. An immersion inspection apparatus (using a relatively high refractive index fluid such as water) may even have a numerical aperture over 1.

As in the lithographic apparatus LA, one or more substrate tables may be provided to hold the substrate W during measurement operations. The substrate tables may be similar or identical in form to the substrate table WT of FIG. 1. In an example where the inspection apparatus is integrated with the lithographic apparatus, they may even be the same substrate table. Coarse and fine positioners may be provided to a second positioner PW configured to accurately position the substrate in relation to a measurement optical system. Various sensors and actuators are provided for example to acquire the position of a target of interest, and to bring it into position under the objective lens 15. Typically many measurements will be made on targets at different locations across the substrate W. The substrate support can be moved in X and Y directions to acquire different targets, and in the Z direction to obtain a desired location of the target relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and only the substrate moves. Provided the relative position of the substrate and the optical system is correct, it does not matter in principle which one of those is moving in the real world, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

The radiation redirected by the substrate W then passes through partially reflecting surface 16 into a detector 18 in order to have the spectrum detected. The detector 18 may be located at a back-projected focal plane 11 (i.e., at the focal length of the lens system 15) or the plane 11 may be re-imaged with auxiliary optics (not shown) onto the detector 18. The detector may be a two-dimensional detector so that a two-dimensional angular scatter spectrum of a substrate target 30 can be measured. The detector 18 may be, for example, an array of CCD or CMOS sensors, and may use an integration time of, for example, 40 milliseconds per frame.

A reference beam may be used, for example, to measure the intensity of the incident radiation. To do this, when the radiation beam is incident on the partially reflecting surface 16 part of it is transmitted through the partially reflecting surface 16 as a reference beam towards a reference mirror 14. The reference beam is then projected onto a different part of the same detector 18 or alternatively on to a different detector (not shown).

One or more interference filters 13 are available to select a wavelength of interest in the range of, say, 405-790 nm or even lower, such as 200-300 nm. The interference filter may be tunable rather than comprising a set of different filters. A grating could be used instead of an interference filter. An aperture stop or spatial light modulator (not shown) may be provided in the illumination path to control the range of angle of incidence of radiation on the target.

The detector 18 may measure the intensity of redirected radiation at a single wavelength (or narrow wavelength range), the intensity separately at multiple wavelengths or integrated over a wavelength range. Furthermore, the detector may separately measure the intensity of transverse magnetic- and transverse electric-polarized radiation and/or the phase difference between the transverse magnetic- and transverse electric-polarized radiation.

The target 30 on substrate W may be a 1-D grating, which is printed such that after development, the bars are formed of solid resist lines. The target 30 may be a 2-D grating, which is printed such that after development, the grating is formed of solid resist pillars or vias in the resist. The bars, pillars or vias may be etched into or on the substrate (e.g., into one or more layers on the substrate). The pattern (e.g., of bars, pillars or vias) is sensitive to change in processing in the patterning process (e.g., optical aberration in the lithographic projection apparatus (particularly the projection system PS), focus change, dose change, etc.) and will manifest in a variation in the printed grating. Accordingly, the measured data of the printed grating is used to reconstruct the grating. One or more parameters of the 1-D grating, such as line width and/or shape, or one or more parameters of the 2-D grating, such as pillar or via width or length or shape, may be input to the reconstruction process, performed by processor PU, from knowledge of the printing step and/or other inspection processes.

In addition to measurement of a parameter by reconstruction, angle resolved scatterometry is useful in the measurement of asymmetry of features in product and/or resist patterns. A particular application of asymmetry measurement is for the measurement of overlay, where the target 30 comprises one set of periodic features superimposed on another. The concepts of asymmetry measurement using the instrument of FIG. 19 or FIG. 15 are described, for example, in U.S. patent application publication US2006-066855, which is incorporated herein in its entirety. Simply stated, while the positions of the diffraction orders in the diffraction spectrum of the target are determined only by the periodicity of the target, asymmetry in the diffraction spectrum is indicative of asymmetry in the individual features which make up the target. In the instrument of FIG. 15, where detector 18 may be an image sensor, such asymmetry in the diffraction orders appears directly as asymmetry in the pupil image recorded by detector 18. This asymmetry can be measured by digital image processing in unit PU, and calibrated against known values of overlay.

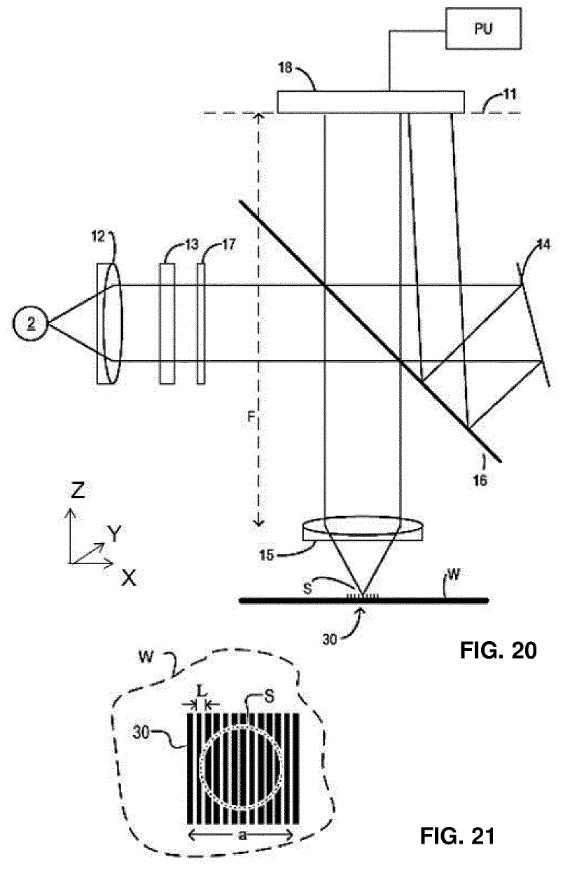

FIG. 21 illustrates a plan view of a typical target 30, and the extent of illumination spot S in the apparatus of FIG. 15. To obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target in other words is ‘underfilled’ by the illumination, and the diffraction signal is essentially free from any signals from product features and the like outside the target itself. The illumination arrangement 2, 12, 13, 17 may be configured to provide illumination of a uniform intensity across a back focal plane of objective 15. Alternatively, by, e.g., including an aperture in the illumination path, illumination may be restricted to on axis or off axis directions.

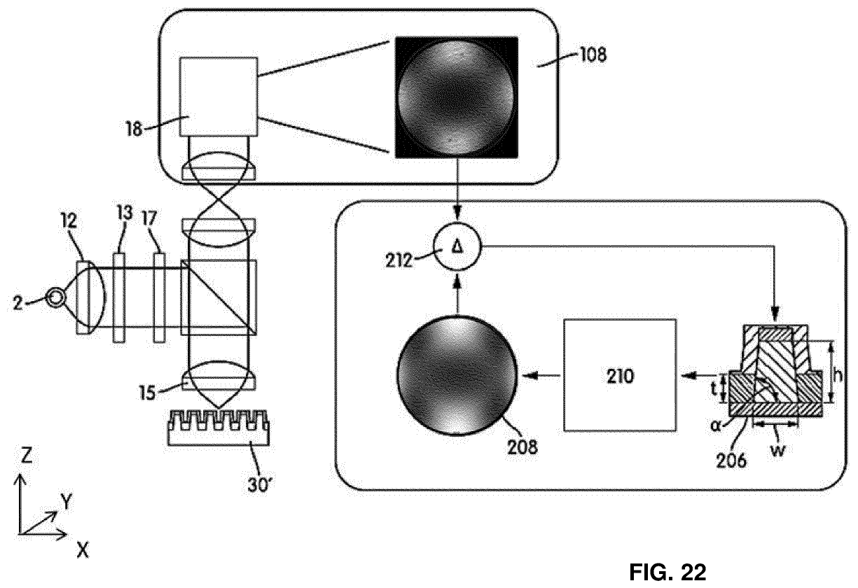

FIG. 22 schematically depicts an example process of the determination of the value of one or more variables of interest of a target pattern 30′ based on measurement data obtained using metrology. Radiation detected by the detector 18 provides a measured radiation distribution 108 for target 30′.

For a given target 30′, a radiation distribution 208 can be computed/simulated from a parameterized model 206 using, for example, a numerical Maxwell solver 210. The parameterized model 206 shows example layers of various materials making up, and associated with, the target. The parameterized model 206 may include one or more of variables for the features and layers of the portion of the target under consideration, which may be varied and derived. As shown in FIG. 22, the one or more of the variables may include the thickness t of one or more layers, a width w (e.g., CD) of one or more features, a height h of one or more features, and/or a sidewall angle a of one or more features. Although not shown, the one or more of the variables may further include, but is not limited to, the refractive index (e.g., a real or complex refractive index, refractive index tensor, etc.) of one or more of the layers, the extinction coefficient of one or more layers, the absorption of one or more layers, resist loss during development, a footing of one or more features, and/or line edge roughness of one or more features. The initial values of the variables may be those expected for the target being measured. The measured radiation distribution 108 is then compared at 212 to the computed radiation distribution 208 to determine the difference between the two. If there is a difference, the values of one or more of the variables of the parameterized model 206 may be varied, a new computed radiation distribution 208 calculated and compared against the measured radiation distribution 108 until there is sufficient match between the measured radiation distribution 108 and the computed radiation distribution 208. At that point, the values of the variables of the parameterized model 206 provide a good or best match of the geometry of the actual target 30′. In an embodiment, there is sufficient match when a difference between the measured radiation distribution 108 and the computed radiation distribution 208 is within a tolerance threshold.

Variables of a patterning process are called “processing variables.” The patterning process may include processes upstream and downstream to the actual transfer of the pattern in a lithography apparatus. The processing variables can be grouped into different categories. The first category may be variables of the lithography apparatus or any other apparatuses used in the lithography process. Examples of this category include variables of the illumination, projection system, substrate stage, etc. of a lithography apparatus. The second category may be variables of one or more procedures performed in the patterning process. Examples of this category include focus control or focus measurement, dose control or dose measurement, bandwidth, exposure duration, development temperature, chemical composition used in development, etc. The third category may be variables of the design layout and its implementation in, or using, a patterning device. Examples of this category may include shapes and/or locations of assist features, adjustments applied by a resolution enhancement technique (RET), CD of mask features, etc. The fourth category may be variables of the substrate. Examples include characteristics of structures under a resist layer, chemical composition and/or physical dimension of the resist layer, etc. The fifth category may be characteristics of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). The sixth category may be characteristics of processes upstream of, or downstream to, pattern transfer in a lithographic apparatus, such as spin coating, post-exposure bake (PEB), development, etching, deposition, doping and/or packaging.

As will be appreciated, many, if not all of these variables, will have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

Further embodiments of the invention are disclosed in the list of numbered clauses below:
1. A method for determining a model to predict a de-corrected overlay data associated with a current substrate being patterned, the method comprising:

obtaining (i) a first data set associated with one or more prior layers and/or current layer of the current substrate being patterned, (ii) a second data set comprising overlay metrology data associated with one or more prior substrates that were patterned before the current substrate, and (iii) measured de-corrected overlay data associated with the current layer of the current substrate; and

determining, based on (i) the first data set, (ii) the second data set, and (iii) the measured data, values of a set of model parameters associated with the model such that the model predicts the de-corrected overlay data for the current substrate,

wherein the values of the model parameters are determined such that a cost function is minimized, the cost function comprises a difference between the predicted data and the measured data.
2. The method of clause 1, wherein the first data set further comprises:

scanner data associated with one or more scanners being used for patterning the one or more prior layers and/or the current layer of the current substrate, and

fabrication context data associated with processing tools that the current substrate was subjected to before the current layer being patterned or will be subjected to after the current layer is patterned.
3. The method of clause 2, wherein the scanner data comprises one or more of:

a scanner identifier and a scanner chuck identifier associated with the one or more scanners;

measurements computed via sensors or a measurement system of the one or more scanners; one or more key performance indicator associated with the one or more scanners and related to an overlay of the current substrate; and

metrology data obtained from alignment sensors, leveling sensors, height sensors, or other sensors attached in the one or more scanners.
4. The method of clause 2, wherein the tools used in of the fabrication comprises one or more of an etch chamber, a chemical mechanical polishing tool, an overlay measurement tool, and/or a CD metrology tool.
5. The method of any of clauses 1-4, wherein the first data set comprises:

overlay metrology data of the one or more prior layers and/or the current layer of the current substrate, the overlay metrology data comprises: (i) measured overlay data obtained after an overlay correction is applied to the one or more prior layers of the current substrate, and/or (ii) de-corrected overlay data obtained before the overlay correction is applied to the one or more prior layers of the current substrate;

alignment metrology data of the one or more prior layers and/or the current layer of the current substrate, the alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on the one or more prior layers, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser;

leveling metrology data of the one or more prior layers and/or the current layer of the current substrate, the leveling metrology data comprises: (i) a substrate height data, and/or (ii) the substrate height data converted to x and y direction displacements; and/or

fabrication context information of the one or more prior layers and/or the current layer of the current substrate, the context information comprises: (i) a lag time associated with a process of the patterning process, (ii) a chuck identifier on which a current substrate was mounted, (iii) a chamber identifier indicating a chamber in which the process of the patterning process was performed, and/or (iv) a chamber fingerprint characterizing an overlay contribution of one or more processing parameters associated with the chamber.
6. The method of any of clauses 1-5, wherein the first data set further comprises:

derived data associated with parameters of the patterning process that cause overlay contribution, wherein the derived data is derived from the scanner data, and/or fabrication context information.
7. The method of any of clauses 1-6, wherein the model is configured to predict the de-corrected overlay data at a point-level of the current substrate, where a point is a location associated with an overlay marker formed on the current substrate.
8. The method of any of clauses 1-7, wherein the model is a point-level model, wherein the values of the model parameter of the point-level model are determined based on the first data set, the second data set, and the measured de-corrected overlay data that are obtained at a given location of a plurality of locations on the current substrate having the overlay marker.
9. The method of clause 8, wherein obtaining the first data the second data set, and the measured de-corrected overlay data set at the given location on the current substrate having the overlay marker comprises:

representing values of the first data set, the second data set, and the measured de-corrected overlay data in form a respective substrate map;

aligning, via modeling and/or interpolation, each of the substrate maps;

sharing substrate-level information, within the first data set, the second data set, and the measured de-corrected overlay data, respectively, uniformly across the current substrate; and

extracting the values of the first data set, the second data set, and the measured de-corrected overlay data, respectively, associated with the given location.
10. The method of clause 9, wherein the substrate-level information comprises at least one of: the chuck identifier, or the lag time associated with the processing tool used in the patterning process of the current substrate.
11. The method of any of clauses 1-2, wherein the model is configured to predict the de-corrected overlay data at a substrate-level.
12. The method of any of clauses 1-11, wherein the model is a substrate-level model, wherein the values of the model parameter of the substrate-level model are determined based on the values of the first data set, the second data set, and the measured de-corrected overlay data across an entire substrate.
13. The method of clause 12, wherein the determining of the values of the model parameter of the substrate-model further comprises:

generating a plurality of substrate maps using values of the first data set, the second data set, and the measured de-corrected overlay data, respectively, associated with each of a plurality of substrates;

projecting each of the plurality of substrate maps to a basis function; and

determining, based on the projecting, projection coefficients associated with the basis function, the projection coefficients and other substrate-level data being used to define the substrate model.
14. The method of clause 13, wherein the projecting the substrate maps on the basis function comprises:

performing a principal component analysis; or

performing a single value decomposition of the substrate maps.
15. The method of any of clauses 13-14, wherein the basis function is a set of Zernike polynomials, and projection coefficients are Zernike coefficients, each Zernike coefficient being associated with a respective Zernike polynomial of the set of Zernike polynomials.
16. The method of any of clauses 1-15, wherein the first data set, the second data set, and the measured de-corrected overlay data are pre-processed to extract desired information from respective data set.
17. The method of clause 16, wherein the desired information is at least one of:

alignment system model residual data;

leveling related residual data; and/or

correctable overlay error data.
18. The method of any of clauses 1-17, wherein the model is at least one of:

a linear model is determined based on (i) the first data set associated with a one selected layer of the current substrate or the prior substrates, or (ii) the first data set associated with multiple layers of the current substrate or the prior substrates; or

a machine learning model.
19. The method of clause 18, wherein the machine learning model is at least one of: multi-layer perceptron; random forest; adaptive boosting trees; support vector regression; Gaussian process regression; or k-nearest neighbors.
20. The method of clauses 18, wherein the machine learning model is an advanced machine learning model including at least one of: a residual neural network (RNN); or a convolutional neural network (CNN).
21. The method of clause 20, wherein the RNN model is formulated to include previous layers of the current substrate or the prior substrates as time axis.
22. The method of any of clauses 1-21, wherein the cost function is at least one of:

a first function, wherein the first mean error is an n-order error is computed using an absolute difference between the predicted data and a reference data, and raising the difference to the n-th order, wherein the predicted data are overlay values associated with the given points on given substrates or the projection coefficients associated with given substrates, and the reference data; or

a second function (M3S) computed using a sum of an absolute of mean and 3time a standard deviation, wherein the mean and the standard deviation are obtained based the difference between the predicted de-corrected overlay data and the reference data, the predicted data are overlay values associated the given points on the given substrates; or

an on product overlay computed using a sum of mean of the M3S and 1.96 times a standard deviation of the M3S, wherein the mean and the standard deviation of the M3S is computed using the predicted data are overlay values associated with a series of given substrates.
23. The method of clause 22, wherein the determining the point-level model comprises:

executing, using data associated with each given location of the plurality of locations on the current substrate, the point-level model using an initial model parameter values to predict the de-corrected overlay data; and

determining, based on the predicted de-corrected overlay data and the measured data at the plurality of locations, values of the model parameters such that the first function, the second function, and/or the on product overlay associated with each given location of the plurality of locations on the given substrate is minimized.
24. The method of clause 22, wherein the determining the substrate-level model comprises:

predicting, using the substrate model, the projection coefficients associated with the basis function;

constructing, based on the predicted projection coefficients, an overlay map;

calculating the first function, the second function, or the on product overlay based on the difference between the constructed overlay map and a reference overlay map; and

determining values of the model parameters such that the first function, the second function or the on product overlay is minimized
25. The method of any of clauses 1-24, wherein the cost function is reduced or minimized using a gradient based method.
26. The method of any of clauses 1-25, wherein, the first data set or the second data set is an incomplete data set, wherein overlay metrology data and/or context data associated with one or more the prior substrates, or one or more prior layers of the current substrate is missing.
27. The method of clause 26, wherein the incomplete overlay data is replaced by an average overlay data, wherein the averaging overlay data is computed based a lot of substrates or grouping of the substrate based on the context data.
28. The method of clause 26, wherein the incomplete overlay data is replaced with domain knowledge-based overlay data, wherein the domain knowledge-based overlay data is generated using computational metrology, wherein the computation metrology comprises an overlay prediction model based on parameters of the patterning process.
29. The method of any of clauses 1-28, wherein the model is structured as a two-level hierarchical model.
30. The method of clause 29, wherein a first level of the hierarchical model is configured to predict overlay data using inputs that are always present including data in the first data set and the second data set, and

a second level of the hierarchical model predicts overlay refinement to the predicted overlay data of the first level based on inputs that are not always present, the inputs including overlay and certain context data.
31. The method of any of clauses 1-30, further comprising:

determining, based on the predicted de-corrected overlay data, overlay corrections or control parameters associated with a patterning apparatus to improve an overlay performance of the patterning apparatus.
32. A method for updating a trained model to predict a de-corrected overlay data associated with a current substrate being patterned, the method comprising:

obtaining (i) first data set associated with one or more prior layers of a current substrate being patterned, (ii) a second data set comprising overlay metrology data associated with one or more prior substrates that were patterned before the current substrate, and (iii) measured de-corrected overlay data associated with the current substrate;

updating, based on the first data set, the second data set, and the measured de-corrected overlay data associated with the current substrate, the trained model such that a cost function associated with the trained model is reduced,

wherein the cost function comprises a difference between a predicted de-corrected overlay data and the measured de-corrected overlay data, the predicted data is obtained via executing the trained model using the first data set and the second data set.
33. The method of clause 32, wherein the cost function is at least one of:

a first function, wherein the first mean error is an n-order error is computed using an absolute difference between the predicted data and a reference data, and raising the difference to the n-th order, wherein the predicted data are overlay values associated with given points on given substrates or projection coefficients associated with the given substrates, and the reference data; or

a second function (M3S) computed using a sum of an absolute of mean and 3 times a standard deviation, wherein the mean and the standard deviation are obtained based the difference between the predicted de-corrected overlay data and the reference data, the predicted data are overlay values associated the given points on the given substrates; or

an on product overlay computed using a sum of mean of the M3S and 1.96 times a standard deviation of the M3S, wherein the mean and the standard deviation of the M3S is computed using the predicted data are overlay values associated with a series of given substrates.
34. The method of any of clauses 32-33, wherein, the first data set or the second data set is an incomplete data set, wherein overlay metrology data and/or context data associated with one or more the prior substrates, or one or more prior layers of the current substrate is missing.
35. The method of clause 34, wherein the incomplete overlay data is replaced by an average overlay data, wherein the averaging overlay data is computed based a lot of substrates or grouping of the substrate based on the context data.
36. The method of clause 34, wherein the incomplete overlay data is replaced with domain knowledge-based overlay data, wherein the domain knowledge-based overlay data is generated using computational metrology, wherein the computation metrology comprises an overlay prediction model based on parameters of the patterning process.
37. A computer program product comprising a non-transitory computer readable medium having instructions recorded thereon, the instructions when executed by a computer implementing the steps of the method of any of clauses 1 to 36.
38. A method of determining overlay corrections for a current substrate to be patterned, the method comprising:

obtaining (i) performance data associated with previously patterned substrates, and (ii) metrology data related to the current substrate to be patterned;

executing, an overlay prediction model using the metrology data related to the current substrate, to predict overlay error induced by a tool used in a patterning process of the current substrate; and

determining, based on the performance data and the predicted overlay error, overlay corrections to be applied to another tool, at which the current substrate will be processed, to compensate for the overlay error induced by the tool.
39. The method according to clause 38, wherein the performance data comprises overlay error data of the previously patterned substrates.
40. The method according to clause 39, wherein the determining of the overlay corrections comprises:

combining the performance data and the predicted overlay error associated with the tool; and

determining substrate adjustments that minimizes the combined overlay error at the another tool being used in a patterning process of the current substrate.
41. The method according to clause 40, wherein the substrate adjustments comprises:

orientation of a substrate table on which the current substrate is mounted; and/or

leveling of the substrate table.
42. The method according to any of clauses 38-41, wherein the overlay prediction model is obtained via:

performing (i) a first principal component analysis (PCA) using alignment data related to the previously patterned substrates or test substrates, and (ii) a second PCA using overlay error data related to the previously patterned substrate or the test substrates; and

establishing a correlation between components of the first PCA and components of the second PCA.
43. The method according to clause 42, wherein the first PCA of the alignment data generates a first set of principal components that explain variations in the alignment data, wherein the first set of principal components include a first set of basis functions and scores associated therewith.
44. The method according to clause 42, wherein the second PCA of the overlay error data generates a second set of principal components that explain variations in the overlay error data, wherein the second set of principal components include a second set of basis functions and scores associated therewith.
45. The method according to clause 44, wherein one or more principal components of the second set of principal components explain overlay error induced by a particular process or a particular tool of the patterning process.
46. The method according to clause 42, wherein the correlation between the first principal components and the second principal components converts the alignment data of the current substrate to predicted overlay error data of the current substrate, the predicted overlay error data is associated with a particular process that the current substrate will be subjected.
47. The method according to any of clauses 38-46, wherein the metrology data comprises:

alignment metrology data associated with the current substrate, the alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on layers of the current substrate, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser; and/or

leveling metrology data of the current substrate, the leveling metrology data comprises: (i) a substrate height data, and/or (ii) the substrate height data converted to x and y direction displacements.
48. The method according to any of clauses 38-47, wherein the performance data is an average overlay error value obtained by averaging the overlay error values associated with the previously patterned substrates.
49. The method according to any of clauses 38-48, wherein the performance data is specific to each tool used in the semiconductor manufacturing process.
50. The method according to any of clauses 38-49, wherein the overlay prediction model is configured to predict overlay error induced by each tool used in the patterning process to the current substrate.
51. The method according to any of clauses 38-50, wherein the tool used in the patterning process comprises: an etching apparatus; a lithographic apparatus; a chemical mechanical polishing apparatus, or a combination thereof.
52. The method according to any of clauses 38-51, wherein the predicted overlay error comprises the overlay error induced by the etching apparatus, the lithographic apparatus, the chemical mechanical polishing apparatus, or a combination thereof.
53. A non-transitory computer-readable media comprising instructions that, when executed by one or more processors, cause operations comprising:

obtaining (i) performance data associated with previously patterned substrates, and (ii) metrology data related to a current substrate to be patterned;

executing, an overlay prediction model using the metrology data associated with the current substrate, to predict overlay error induced by a tool used in a patterning process of the current substrate; and

determining, based on the performance data and the predicted overlay error, overlay corrections to be applied to another tool, at which the current substrate will be processed, to compensate for the overlay error induced by the tool.
54. The non-transitory computer-readable media according to clause 53, wherein the determining of the overlay corrections comprises:

combining the performance data and the predicted overlay error associated with the tool; and

determining substrate adjustments that minimizes the combined overlay error at another tool being used on the current substrate.
55. The non-transitory computer-readable media according to any of clauses 53-54, wherein the overlay prediction model is obtained via:

performing (i) a first principal component analysis (PCA) using the alignment data related to the previously patterned substrate or test substrates, and (ii) a second PCA using overlay error data related to the previously patterned substrate or the test substrates; and

establishing a correlation between components of the first PCA and components of the second PCA.
56. The non-transitory computer-readable media according to clause 55, wherein the first PCA of the alignment data generates a first set of principal components that explain variations in the alignment data, wherein the first set of principal components include a first set of basis functions and scores associated therewith.
57. The non-transitory computer-readable media according to clause 55, wherein the second PCA of the overlay error data generates a second set of principal components that explain variations in the overlay error data, wherein the second set of principal components include a second set of basis functions and scores associated therewith.
58. The non-transitory computer-readable media according to clause 55, wherein the correlation between the first principal components and the second principal components converts the alignment data of the current substrate to predicted overlay error data of the current substrate, the predicted overlay error data is associated with a particular process that the current substrate will be subjected.
59. The non-transitory computer-readable media according to any of clauses 53-58, wherein the metrology data comprises:

alignment metrology data associated with the current substrate, the alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on layers of the current substrate, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser; and/or

leveling metrology data of the current substrate, the leveling metrology data comprises: (i) a substrate height data, and/or (ii) the substrate height data converted to x and y direction displacements.
60. The non-transitory computer-readable media of any according to clauses 53-59, wherein the performance data is an average overlay error value obtained by averaging the overlay error values associated with the previously patterned substrates.
61. The non-transitory computer-readable media according to any of clauses 53-60, wherein the overlay prediction model is configured to predict overlay error induced by each tool used in the patterning process to the current substrate.
62. A system for overlay corrections for a current substrate to be patterned, the system comprising:

a semiconductor manufacturing apparatus;

a metrology tool for capturing metrology data related to the current substrate to be patterned;

a processor configured to:
execute, an overlay prediction model using the metrology data associated with the current substrate, to predict overlay error induced by the semiconductor manufacturing apparatus used in a patterning process of the current substrate; and
determine, based on the performance data and the predicted overlay error, overlay corrections to be applied to another tool, at which the current substrate will be processed, to compensate for the overlay error induced by the tool.
63. The system according to clause 62, wherein the processor is configured to determine of the overlay corrections by:

combining the performance data and the predicted overlay error associated with the semiconductor manufacturing apparatus; and

determining substrate adjustments that minimizes the combined overlay error at another semiconductor manufacturing apparatus being used on the current substrate.
64. The system according to any of clauses 62-63, wherein the processor is further configured to obtain the overlay prediction model by:

performing (i) a first principal component analysis (PCA) using the alignment data related to the previously patterned substrate or test substrates, and (ii) a second PCA using overlay error data related to the previously patterned substrate or the test substrates; and

establishing a correlation between components of the first PCA and components of the second PCA.
65. The system according to clause 64, wherein the correlation between first principal components and second principal components converts the alignment data of the current substrate to predicted overlay error data of the current substrate, the predicted overlay error data is associated with a particular process that the current substrate will be subjected.
66. The system according to any of clauses 62-65, wherein the metrology data comprises:

alignment metrology data associated with the current substrate, the alignment metrology data comprises: (i) alignment sensor data, (ii) residual map generated via an alignment system model, (iii) a substrate quality map comprising signals of varying strength, the substrate quality map indicative of reliability of the alignment data, and/or (iv) color2color difference maps obtained via projecting a plurality of colored-laser beams on the substrate, each colored-laser beam reflecting from an alignment mark on layers of the current substrate, the reflected beam generating a diffraction pattern, the color2color difference map being a difference between a first diffraction pattern and a second diffraction pattern, the first diffraction pattern being associated with a first color of the plurality of colored-laser and the second diffraction pattern being associated with a second color of the plurality of colored-laser; and/or

leveling metrology data of the current substrate, the leveling metrology data comprises: (i) a substrate height data, and/or (ii) the substrate height data converted to x and y direction displacements.
67. The system according to any of clauses 62-66, wherein the performance data is an average overlay error value obtained by averaging the overlay error values associated with the previously patterned substrates.
68. The system according to any of clauses 62-67, wherein the semiconductor manufacturing apparatus used in the patterning process comprises: an etching apparatus; a lithographic apparatus; a chemical mechanical polishing apparatus, or a combination thereof.
69. The system according to any of clauses 62-68, wherein the overlay prediction model is configured to predict overlay error induced by each tool used in the patterning process to the current substrate.
70. A non-transitory computer readable medium having instructions thereon, the instructions when executed by a computer causing the computer to:

obtain first performance data associated with portions of a plurality of patterned substrate layers of a substrate;

generate, via a trained model using the first performance data, predicted performance data relating to one or more portions of a future layer that will be formed on the substrate; and

generate, based on the first performance data associated with the patterned substrate layers and the predicted performance data associated with the future layer, values of one or more parameters for controlling a patterning process to cause a second performance data associated with the future layer of the substrate to be within a specified performance range.
71. The non-transitory computer readable medium of clause 70, wherein the first performance data comprises substrate-level performance data associated with a current lot of patterned substrates.
72. The non-transitory computer readable medium of clause 71, wherein the first performance data further comprises substrate-level performance data associated with a previous lot of patterned substrates.
73. The non-transitory computer readable medium of any of clauses 70-72, wherein the trained model is configured to correlate the first performance data associated with a first layer with one or more other patterned substrate layers.
74. The non-transitory computer readable medium of any of clauses 70-73, wherein the first performance data comprises:
performance data associated with a first layer of the substrate; and
another performance data associated with a second layer of the substrate, the second layer being located below the first layer of the substrate.
75. The non-transitory computer readable medium of any of clauses 70-74, wherein the portions of the patterned substrate layers are aligned.
76. The non-transitory computer readable medium of any of clauses 70-75, wherein instructions to generate values of the one or more parameters comprise:
determine, based on the first performance data, de-corrected performance data associated with the patterned substrate layers;
determine, based on the predicted performance data relating to the one or more portions of the further layer, substrate-level performance data of the future layer;
adjust, based on the substrate-level performance data of the future layer and the de-corrected performance data of the patterned substrate layers, values of one or more parameters of the patterning process to cause the performance data of the future layer of the substrate to be within the specified performance range after patterning.
78. The non-transitory computer readable medium of any of clauses 70-77, wherein the portion of the substrate is a field, a sub-field, or a die area of the substrate.
79. The non-transitory computer readable medium of any of clauses 70-78, wherein the first performance data comprising the substrate-level performance data is divided into portion specific performance data.
80. The non-transitory computer readable medium of any of clauses 70-79, wherein the one or more parameters comprises: dose, focus, alignment of the substrate with respect to a reference, height of the substrate, layer thickness, deposition process parameters, and/or etch process parameters.
81. The non-transitory computer readable medium of any of clauses 70-80, wherein the first performance data and the predicted performance data comprises at least one of:

overlay data associated with a given layer of the substrate;

alignment data associated with the given layer of the substrate;

leveling data associated with the given layer of the substrate;

correctable overlay error data associated with the given layer of the substrate, or

height data of the given layer with respect to one or more bottom layers on the substrate.
82. The non-transitory computer readable medium of any of clauses 70-81, wherein the trained model is at least one of: a linear model; or a machine learning model.
83. The non-transitory computer readable medium of clause 82, wherein the machine learning model is at least one of: multi-layer perceptron; random forest; adaptive boosting trees; support vector regression; Gaussian process regression; or k-nearest neighbors.
84. The non-transitory computer readable medium of clause 82, wherein the machine learning model is an advanced machine learning model including at least one of: a residual neural network (RNN); or a convolutional neural network (CNN).
85. The non-transitory computer readable medium of clause 84, wherein the RNN model is formulated to include data related to the patterned substrate layers as time axis.
86. One or more non-transitory, computer-readable media storing a prediction model and instructions that, when executed by one or more processors, provides the prediction model, the prediction model being produced by:

obtaining performance data associated with portions of a plurality of patterned substrate layers formed one on top of another;

providing the performance data of the portions of the patterned substrate layers as input to a base prediction model to obtain predicted performance data associated with the portions of a first layer of the substrate; and

using the inputted performance data associated with the first layer as feedback to update one or more configurations of the base prediction model, wherein the one or more configurations are updated based on a comparison between the inputted performance data and the predicted performance data of the first layer,

wherein the prediction model is structured to correlate the performance data of the first layer with one or more other patterned substrate layers.
87. The medium of clause 86, wherein the obtaining of the performance data comprises:

splitting the performance data according to one or more portions of the substrate.
88. The medium of any of clauses 86-87, wherein the training of the model is an iterative process, each iteration comprising:

predicting, via the base prediction model using the performance data associated with the portions and given model parameter values, the performance data associated with the portions of the first layer;

comparing the model predicted performance data associated with the portions of the first layer with the obtained performance data associated with the portions of the first layer;

adjusting, based on the difference, the given model parameter values of the base model to cause a difference between the model-predicted performance data and the obtained performance data associated with portions of the first layer of the plurality of patterned substrate layers to be within a specified range.
89. The medium of clause 88, wherein the adjusting of the given model parameter values of the model is performed until the difference is minimized
90. The medium of any of clauses 86-89, wherein the model is at least one of: a linear model; or a machine learning model.
91. The medium of clause 90, wherein the machine learning model is at least one of: multi-layer perceptron; random forest; adaptive boosting trees; support vector regression; Gaussian process regression; or k-nearest neighbors.
92. The medium of clause 90, wherein the machine learning model is an advanced machine learning model including at least one of: a residual neural network (RNN); or a convolutional neural network (CNN).
93. The medium of clause 92, wherein the RNN model is formulated to include patterned substrate layers of a current lot of substrates or patterned substrate layers of a prior of substrates as time axis.
94. The medium of any of clauses 86-93, wherein the plurality of portions of the patterned substrate layers are fields, sub-fields, or die areas of the substrate.
95. The medium of any of clauses 86-94, wherein the performance data comprise at least one of:

overlay data associated with a given layer of the substrate;

alignment data associated with the given layer of the substrate;

leveling data associated with the given layer of the substrate;

correctable overlay error data associated with the given layer of the substrate, or

height data of the given layer with respect to one or more bottom layers on the substrate.

FIG. 23 is a block diagram that illustrates a computer system 100 which can assist in implementing the methods, flows or the apparatus disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126.

ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide all or part of a method described herein, for example. The received code may be executed by processor 104 as it is received, and/or stored in storage device 110, or other non-volatile storage for later execution. In this manner, computer system 100 may obtain application code in the form of a carrier wave.

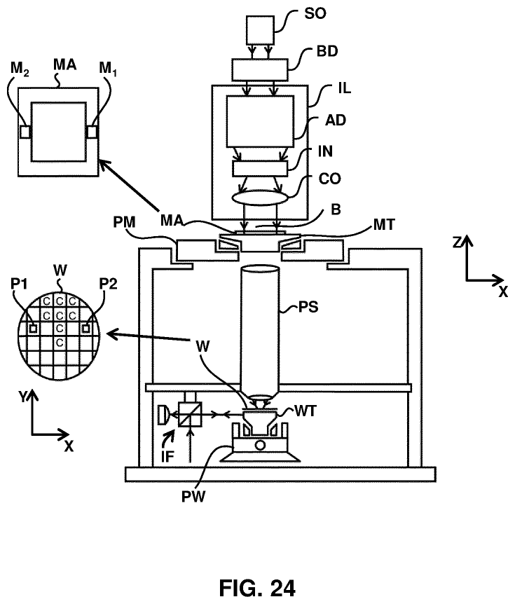

FIG. 24 schematically depicts an exemplary lithographic projection apparatus in conjunction with the techniques described herein can be utilized. The apparatus comprises:

an illumination system IL, to condition a beam B of radiation. In this particular case, the illumination system also comprises a radiation source SO;

a first object table (e.g., patterning device table) MT provided with a patterning device holder to hold a patterning device MA (e.g., a reticle), and connected to a first positioner to accurately position the patterning device with respect to item PS;

a second object table (substrate table) WT provided with a substrate holder to hold a substrate W (e.g., a resist-coated silicon wafer), and connected to a second positioner to accurately position the substrate with respect to item PS;

a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as a-outer and a-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 24 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 24. However, in the case of a stepper (as opposed to a step-and-scan tool) the patterning device table MT may just be connected to a short stroke actuator, or may be fixed.

The depicted tool can be used in two different modes:

In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;

In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

FIG. 25 schematically depicts another exemplary lithographic projection apparatus 1000 in conjunction with the techniques described herein can be utilized.

The lithographic projection apparatus 1000 comprises:
a source collector module SO
an illumination system (illuminator) IL configured to condition a radiation beam B (e.g. EUV radiation).
a support structure (e.g. a patterning device table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective patterning device). It is to be noted that because most materials are absorptive within the EUV wavelength range, the patterning device may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 25, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 25, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:

1. In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. patterning device table) MT and the substrate table WT are scanned synchronously while a pattern imparted to the radiation beam is projected onto a target portion C (i.e. a single dynamic exposure). The velocity and direction of the substrate table WT relative to the support structure (e.g. patterning device table) MT may be determined by the (de-)magnification and image reversal characteristics of the projection system PS.

3. In another mode, the support structure (e.g. patterning device table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

FIG. 26 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 26.

Collector optic CO, as illustrated in FIG. 26, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

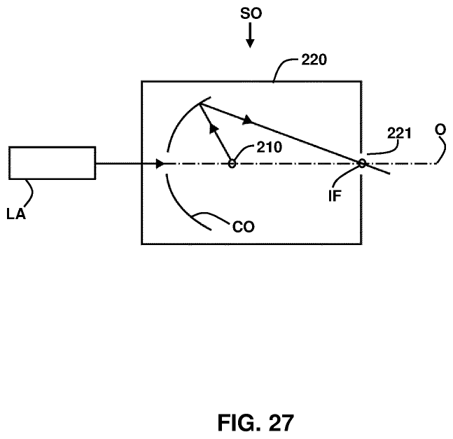

Alternatively, the source collector module SO may be part of an LPP radiation system as shown in FIG. 27. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A method for determining a model to predict overlay data associated with a current substrate being patterned, the method comprising:
obtaining (i) a first data set associated with one or more prior layers and/or current layer of the current substrate being patterned, (ii) a second data set comprising overlay metrology data associated with one or more prior substrates that were patterned before the current substrate, and (iii) de-corrected measured overlay data associated with the current layer of the current substrate; and
determining, by a hardware computer and based on (i) the first data set, (ii) the second data set, and (iii) the de-corrected measured overlay data, values of a set of model parameters associated with the model such that the model predicts the overlay data for the current substrate,
wherein the values of the set of model parameters are determined such that a cost function is minimized, the cost function comprising a difference between the predicted overlay data and the de-corrected measured overlay data.

2. The method of claim 1, wherein the first data set further comprises:
lithographic apparatus data associated with one or more lithographic apparatuses used for patterning the one or more prior layers and/or the current layer of the current substrate, and
fabrication context data associated with one or more processing tools that the current substrate was subjected to before the current layer being patterned or will be subjected to after the current layer is patterned.

3. The method of claim 2, wherein the lithographic apparatus data comprises one or more selected from:
a lithographic apparatus identifier and a lithographic apparatus chuck identifier associated with the one or more lithographic apparatuses;
measurements computed via one or more sensors or a measurement system of the one or more lithographic apparatuses;
one or more key performance indicators associated with the one or more lithographic apparatuses and related to an overlay of the current substrate; and/or
metrology data obtained from one or more alignment sensors, one or more leveling sensors, one or more height sensors, or one or more other sensors attached in the one or more lithographic apparatuses.

4. The method of claim 2, wherein the one or more processing tools comprise one or more selected from: an etch chamber, a chemical mechanical polishing tool, an overlay measurement tool, and/or a critical dimension (CD) metrology tool.

5. The method of claim 1, wherein the first data set comprises:
overlay metrology data of the one or more prior layers and/or the current layer of the current substrate, the overlay metrology data comprising: (i) measured overlay data obtained after an overlay correction is applied to the one or more prior layers of the current substrate, and/or (ii) de-corrected overlay data obtained before the overlay correction is applied to the one or more prior layers of the current substrate;
alignment metrology data of the one or more prior layers and/or the current layer of the current substrate, the alignment metrology data comprising: (i) alignment sensor data, (ii) a residual map generated via an alignment system model, (iii) a substrate quality map comprising signals of varying strength, the substrate quality map indicative of reliability of the alignment data, and/or (iv) a color2color difference map obtained via projection of a plurality of colored-laser beams on the substrate, each colored-laser beam reflecting from an alignment mark on the one or more prior layers, the respective reflected beam generating a diffraction pattern, the color2color difference map being a difference between a first diffraction pattern and a second diffraction pattern, the first diffraction pattern being associated with a first color of the plurality of colored-laser beams and the second diffraction pattern being associated with a second color of the plurality of colored-laser beams;
leveling metrology data of the one or more prior layers and/or the current layer of the current substrate, the leveling metrology data comprising: (i) a substrate height data, and/or (ii) the substrate height data converted to x and y direction displacements; and/or
fabrication context information of the one or more prior layers and/or the current layer of the current substrate, the context information comprising: (i) a lag time associated with a process of the patterning process, (ii) a chuck identifier on which a current substrate was mounted, (iii) a chamber identifier indicating a chamber in which a process of the patterning process was performed, and/or (iv) a chamber fingerprint characterizing an overlay contribution of one or more processing parameters associated with the chamber.

6. The method of claim 1, wherein the first data set further comprises derived data associated with one or more parameters of the patterning process associated with a contribution to overlay, wherein the derived data is derived from the lithographic apparatus data and/or fabrication context information.

7. The method of claim 1, wherein the model is configured to predict tho overlay data at a point-level of the current substrate, where a point is a location associated with an overlay mark formed on the current substrate.

8. The method of claim 1, wherein the model is a point-level model, wherein the values of the set of model parameters of the point-level model are determined based on the first data set, the second data set, and the de-corrected measured overlay data that are obtained at a given location of a plurality of locations on the current substrate having an overlay mark.

9. The method of claim 8, wherein obtaining the first data set, the second data set, and the de-corrected measured overlay data at the given location on the current substrate having the overlay mark comprises:
representing values of the first data set, the second data set, and the de-corrected measured overlay data in the form of a respective substrate map;
aligning, via modeling and/or interpolation, each of the substrate maps;
sharing substrate-level information, within the first data set, the second data set, and the de-corrected measured overlay data, respectively, uniformly across the current substrate; and
extracting the values of the first data set, the second data set, and the de-corrected measured overlay data, respectively, associated with the given location.

10. The method of claim 1, wherein the model is a substrate-level model, and wherein the values of the set of model parameters of the substrate-level model are determined based on the values of the first data set, the second data set, and the de-corrected measured overlay data across an entire substrate.

11. The method of claim 10, wherein the determining of the values of the set of model parameters of the substrate-level model further comprises:
generating a plurality of substrate maps using values of the first data set, the second data set, and the de-corrected measured overlay data, respectively, associated with each of a plurality of substrates;
projecting each of the plurality of substrate maps to a basis function; and
determining, based on the projecting, projection coefficients associated with the basis function, the projection coefficients and other substrate-level data being used to define the substrate model.

12. The method of claim 1, wherein the model is at least one selected from:
a linear model that is determined based on (i) the first data set associated with a selected layer of the current substrate or the prior substrates, or (ii) the first data set associated with multiple layers of the current substrate or the prior substrates; or
a machine learning model.

13. The method of claim 12, wherein the model is a machine learning model and wherein the machine learning model is at least one selected from: multi-layer perceptron, random forest, adaptive boosting trees, support vector regression, Gaussian process regression, or k-nearest neighbors.

14. The method of claim 12, wherein the model is a machine learning model and wherein the machine learning model is an advanced machine learning model including at least one selected from: a residual neural network (RNN) or a convolutional neural network (CNN).

15. A computer program product comprising a non-transitory computer readable medium having instructions therein, the instructions, when executed by a computer system, configured to cause the computer system to at least:
obtain (i) a first data set associated with one or more prior layers and/or current layer of the current substrate being patterned, (ii) a second data set comprising overlay metrology data associated with one or more prior substrates that were patterned before the current substrate, and (iii) de-corrected measured overlay data associated with the current layer of the current substrate; and
determine, based on (i) the first data set, (ii) the second data set, and (iii) the de-corrected measured overlay data, values of a set of model parameters associated with a model for predicting overlay data associated with the current substrate being patterned such that the model predicts overlay data for the current substrate,
wherein the values of the set of model parameters are determined such that a cost function is minimized, the cost function comprising a difference between the predicted overlay data and the de-corrected measured overlay data.

16. The computer program product of claim 15, wherein the model is a substrate-level model, and wherein the values of the set of model parameters of the substrate-level model are determined based on the values of the first data set, the second data set, and the de-corrected measured overlay data across an entire substrate.

17. The computer program product of claim 16, wherein the instructions are further configured to:
generate a plurality of substrate maps using values of the first data set, the second data set, and the de-corrected measured overlay data, respectively, associated with each of a plurality of substrates;
project each of the plurality of substrate maps to a basis function; and
determine, based on the projecting, projection coefficients associated with the basis function, the projection coefficients and other substrate-level data being used to define the substrate model.

18. The computer program product of claim 15, wherein the model is at least selected from:
a linear model that is determined based on (i) the first data set associated with a selected layer of the current substrate or the prior substrates, or (ii) the first data set associated with multiple layers of the current substrate or the prior substrates; or
a machine learning model.

19. The computer program product of claim 18, wherein the model is a machine learning model and the machine learning model is at least selected from: multi-layer perceptron, random forest, adaptive boosting trees, support vector regression, Gaussian process regression, or k-nearest neighbors.

20. The computer program product of claim 18, wherein the model is a machine learning model and the machine learning model is a machine learning model including at least one selected from: a residual neural network (RNN) or a convolutional neural network (CNN).
